(19) United States
(12) Patent Application Publication
(10) Pub. No.: US 2024/0021404 A1
(43) Pub. Date: Jan. 18, 2024

(54) CHARGED-PARTICLE BEAM APPARATUS WITH BEAM-TILT AND METHODS THEREOF

(71) Applicant: ASML Netherlands B.V., Veldhoven (NL)

(72) Inventors: Weiming REN, San Jose, CA (US); Xuedong LIU, San Jose, CA (US); Shahedul HOQUE, Milpitas, CA (US); Xiaoyu JI, San Jose, CA (US); Hermanus Adrianus DILLEN, Maarheeze (NL)

(73) Assignee: ASML Netherlands B.V., Veldhoven (NL)

(21) Appl. No.: 18/256,865

(22) PCT Filed: Nov. 17, 2021
(86) PCT No.: PCT/EP2021/081924

§ 371 Date: Jun. 9, 2023

Related U.S. Application Data
(60) Provisional application No. 63/123,967, filed on Dec. 10, 2020.
(60) Provisional application No. 63/242,852, filed on Sep. 10, 2021.

(51) Int. Cl. H01J 37/147

(52) U.S. Cl. CPC H01J 37/1478; H01J 37/1477; H01J 2237/1507; H01J 37/28

(57) ABSTRACT

Systems and methods of imaging a sample using a tilted charged-particle beam. The apparatus may comprise a first deflector located between the charged-particle source and an objective lens and configured to deflect the charged-particle beam away from the primary optical axis; a second deflector located substantially at a focal plane of the objective lens and configured to deflect the charged-particle beam back towards the primary optical axis; and a third deflector located substantially at a principal plane of the objective lens, wherein the third deflector is configured to shift a wobbling center of the objective lens to an off-axis wobbling location, and wherein the first and the second deflectors are configured to deflect the charged-particle beam to pass through the off-axis wobbling location to land on a surface of a sample at a first landing location and having a beam-tilt angle.

### CROSS-REFERENCE TO RELATED APPLICATIONS

This application claims priority of U.S. application 63/123,967 which was filed on Dec. 10, 2020 and U.S. application 63/242,852 which was filed on Sep. 10, 2021 which are incorporated herein in its entirety by reference.

### TECHNICAL FIELD

The embodiments provided herein disclose a charged-particle beam apparatus, and more particularly an electron beam metrology and inspection apparatus with a beam-tilt function to inspect complex structures and capture high-resolution images thereof.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. As the physical sizes of IC components continue to shrink, accuracy and yield in defect detection become more important. Although beam-tilting function may improve the accessibility of complex structures such as angled holes, vias, etc., the off-axis aberrations introduced by the design modifications to perform beam-tilting may render the technique and the inspection tools inadequate for their desired purpose.

### SUMMARY

One aspect of the present disclosure is directed to a charged-particle beam apparatus comprising a charged-particle source configured to generate a charged-particle beam along a primary optical axis. The apparatus may further comprise a first deflector configured to deflect the charged-particle beam to land on a surface of a sample at a beam-tilt angle, wherein the first deflector is located substantially at a principal plane of an objective lens.

Another aspect of the present disclosure is directed to a charged-particle beam apparatus comprising a charged-particle source configured to generate a charged-particle beam along a primary optical axis. The apparatus may further comprise a first deflector configured to deflect the charged-particle beam away from the primary optical axis; and a second deflector configured to deflect the charged-particle beam back towards the primary optical axis so as to pass through a wobbling center of an objective lens and land on a surface of a sample at a beam-tilt angle, wherein the second deflector is positioned between the first deflector and the sample.

Another aspect of the present disclosure is directed to a charged-particle beam apparatus comprising a charged-particle source configured to generate a charged-particle beam along a primary optical axis. The apparatus may further comprise a first deflector located between the charged-particle source and an objective lens and configured to deflect the charged-particle beam away from the primary optical axis; a second deflector located substantially at a focal plane of the objective lens and configured to deflect the charged-particle beam back towards the primary optical axis; and a third deflector located substantially at a principal plane of the objective lens, wherein the third deflector is configured to shift a wobbling center of the objective lens to an off-axis wobbling location, and wherein the first and the second deflectors are configured to deflect the charged-particle beam to pass through the off-axis wobbling location to land on a surface of a sample at a first landing location and having a beam-tilt angle.

Another aspect of the present disclosure is directed to a charged-particle beam apparatus comprising a charged-particle source configured to generate a charged-particle beam along a primary optical axis; a first deflector located between the charged-particle source and an objective lens and configured to deflect the charged-particle beam away from the primary optical axis; a second deflector located substantially at a focal plane of the objective lens and configured to deflect the charged-particle beam back towards the primary optical axis; and a third deflector located substantially at a principal plane of the objective lens, wherein the first and the second deflectors are further configured to deflect the charged-particle beam to scan a field-of-view (FOV) on a surface of a sample, and wherein the third deflector is configured to shift a wobbling center of the objective lens to an off-axis wobbling location such that the charged-particle beam passes through the wobbling center of the objective lens.

Another aspect of the present disclosure is directed to a charged-particle beam apparatus comprising a charged-particle source configured to generate a charged-particle beam along a primary optical axis; a first deflector located between the charged-particle source and an objective lens and configured to deflect the charged-particle beam away from the primary optical axis; a second deflector located between the first deflector and the objective lens and configured to deflect the charged-particle beam to pass through a coma-free point on a coma-free plane of the objective lens; and a dispersion compensator located between the charged-particle source and the first deflector along the primary optical axis.

Another aspect of the present disclosure is directed to a method for imaging a sample using a tilted charged-particle beam. The method may comprise generating a charged-particle beam along a primary optical axis; and deflecting, using a first deflector, the charged-particle beam to land on a surface of a sample at a beam-tilt angle, wherein the first deflector is located substantially at a principal plane of an objective lens.

Another aspect of the present disclosure is directed to a method for imaging a sample using a tilted charged-particle beam. The method may comprise generating a charged-particle beam along a primary optical axis; deflecting, using a first deflector, the charged-particle beam away from the primary optical axis; and deflecting, using a second deflector, the charged-particle beam back towards the primary optical axis so as to pass through a wobbling center of an objective lens and land on a surface of a sample at a beam-tilt angle.

Another aspect of the present disclosure is directed to a method for imaging a sample using a tilted charged-particle beam. The method may comprise generating a charged-particle beam along a primary optical axis; deflecting, using a first deflector, the charged-particle beam away from the primary optical axis, the first deflector located between a charged-particle source and an objective lens; deflecting, using a second deflector, the charged-particle beam back towards the primary optical axis; and shifting, using a third deflector, a wobbling center of the objective lens to an off-axis wobbling location, wherein the first and the second deflectors are configured to deflect the charged-particle beam to pass through the off-axis wobbling location to land on a surface of a sample at a first landing location and having a beam-tilt angle.

Another aspect of the present disclosure is directed to a method for imaging a sample using a tilted charged-particle beam. The method may comprise generating a charged-particle beam along a primary optical axis; deflecting, using a first deflector, the charged-particle beam away from the primary optical axis, the first deflector located between a charged-particle source and an objective lens; deflecting, using a second deflector, the charged-particle beam back towards the primary optical axis, the second deflector located substantially at a focal plane of the objective lens; and shifting, using a third deflector, a wobbling center of the objective lens, wherein the first and the second deflectors are further configured to deflect the charged-particle beam to scan a field-of-view (FOV) on a surface of a sample, and wherein the third deflector is configured to shift the wobbling center of the objective lens to an off-axis wobbling location such that the charged-particle beam passes through the wobbling center of the objective lens.

Another aspect of the present disclosure is directed to a method for imaging a sample using a tilted charged-particle beam. The method may comprise generating a charged-particle beam along a primary optical axis; deflecting, using a first deflector, the charged-particle beam away from the primary optical axis; and deflecting, using a second deflector, the charged-particle beam to pass through a coma-free point on a coma-free plane of an objective lens, wherein the second beam deflector is located between the first deflector and the objective lens.

Another aspect of the present disclosure is directed to a non-transitory computer readable medium storing a set of instructions that is executable by one or more processors of a charged-particle beam apparatus to cause the charged-particle beam apparatus to perform a method of imaging a sample using a tilted charged-particle beam. The method may comprise activating a charged-particle source to generate a primary charged-particle beam; deflecting, at a first deflector, the charged-particle beam to land on a surface of a sample at a beam-tilt angle, wherein the first deflector is located substantially at a principal plane of an objective lens.

Another aspect of the present disclosure is directed to a non-transitory computer readable medium storing a set of instructions that is executable by one or more processors of a charged-particle beam apparatus to cause the charged-particle beam apparatus to perform a method of imaging a sample using a tilted charged-particle beam. The method may comprise activating a charged-particle source to generate a primary charged-particle beam; deflecting the charged-particle beam away from a primary optical axis; and deflecting the charged-particle beam back towards the primary optical axis so as to pass through a wobbling center of an objective lens and land on a surface of a sample at a beam-tilt angle.

Another aspect of the present disclosure is directed to a non-transitory computer readable medium storing a set of instructions that is executable by one or more processors of a charged-particle beam apparatus to cause the charged-particle beam apparatus to perform a method of imaging a sample using a tilted charged-particle beam. The method may comprise activating a charged-particle source to generate a primary charged-particle beam; deflecting, using a first deflector, the charged-particle beam away from the primary optical axis; deflecting, using a second deflector, the charged-particle beam back towards the primary optical axis; and shifting, using a third deflector, a wobbling center of the objective lens, wherein the first and the second deflectors are further configured to deflect the charged-particle beam to scan a field-of-view (FOV) on a surface of a sample, and wherein the third deflector is configured to shift the wobbling center of the objective lens to an off-axis wobbling location such that the charged-particle beam passes through the wobbling center of the objective lens.

Another aspect of the present disclosure is directed to a non-transitory computer readable medium storing a set of instructions that is executable by one or more processors of a charged-particle beam apparatus to cause the charged-particle beam apparatus to perform a method of imaging a sample using a tilted charged-particle beam. The method may comprise activating a charged-particle source to generate a primary charged-particle beam; deflecting the charged-particle beam away from the primary optical axis; and deflecting the charged-particle beam to pass through a coma-free point on a coma-free plane of an objective lens.

Another aspect of the present disclosure is directed to a charged-particle beam apparatus comprising a charged-particle source configured to generate a charged-particle beam along a primary optical axis. The apparatus may further comprise a first deflector located substantially at a principal plane of an objective lens and configured to deflect the charged-particle beam to land on a surface of a sample at a beam-tilt angle. The apparatus may further comprise a controller having circuitry configured to adjust an electrical excitation signal applied to the first deflector to cause an adjustment of the beam-tilt angle of the charged-particle beam and determine a characteristic of a feature being imaged by the adjusted beam-tilt angle of the charged-particle beam, wherein the adjustment of the electrical excitation signal is based on a predetermined dimension of the feature being imaged. Another aspect of the present disclosure is directed to a method of imaging sample using a

tilted charged-particle beam. The method may comprise generating a charged-particle beam along a primary optical axis, deflecting, using a first deflector, the charged-particle beam to land on a surface of a sample at a beam-tilt angle and at an off-axis location, wherein the first deflector is located substantially at a principal plane of an objective lens; adjusting an electrical excitation signal applied to the first deflector to adjust the beam-tilt angle of the charged-particle beam; and determining a characteristic of a feature being imaged by the adjusted beam-tilt angle of the charged-particle beam, wherein the first electrical excitation signal is adjusted based on a predetermined dimension of the feature being imaged.

Another aspect of the present disclosure is directed to a non-transitory computer readable medium storing a set of instructions that is executable by one or more processors of a charged-particle beam apparatus to cause the charged-particle beam apparatus to perform a method of imaging a sample using a tilted charged-particle beam. The method may include generating a charged-particle beam along a primary optical axis, deflecting, using a first deflector, the charged-particle beam to land on a surface of a sample at a beam-tilt angle and at an off-axis location, wherein the first deflector is located substantially at a principal plane of an objective lens, adjusting an electrical excitation signal applied to the first deflector to adjust the beam-tilt angle of the charged-particle beam, and determining a characteristic of a feature being imaged by the adjusted beam-tilt angle of the charged-particle beam, wherein the first electrical excitation signal is adjusted based on a predetermined dimension of the feature being imaged.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a schematic diagram illustrating an exemplary electron beam inspection (EBI) system, consistent with embodiments of the present disclosure.

FIG. 2 is a schematic diagram illustrating an exemplary electron beam tool that can be a part of the exemplary electron beam inspection system of FIG. 1, consistent with embodiments of the present disclosure.

FIG. 3 is a schematic diagram illustrating an exemplary electron beam tool with a beam-tilt function.

FIG. 4 is a schematic diagram illustrating an exemplary electron beam tool with a beam-tilt function, consistent with embodiments of the present disclosure.

FIG. 5 is a schematic diagram illustrating an exemplary electron beam tool with a beam-tilt function, consistent with embodiments of the present disclosure.

FIG. 6 is a schematic diagram illustrating an exemplary electron beam tool with a beam-tilt function, consistent with embodiments of the present disclosure.

FIG. 7 is a schematic diagram illustrating an exemplary electron beam tool with a beam-tilt function, consistent with embodiments of the present disclosure.

FIG. 8 is a schematic diagram illustrating an exemplary electron beam tool with a beam-tilt function, consistent with embodiments of the present disclosure.

FIG. 9 is a schematic diagram illustrating an exemplary electron beam tool with a beam-tilt function, consistent with embodiments of the present disclosure.

FIG. 10 is a schematic diagram illustrating an exemplary electron beam tool with a beam-tilt function, consistent with embodiments of the present disclosure.

FIG. 11 is a schematic diagram illustrating an exemplary electron beam tool with a beam-tilt function, consistent with embodiments of the present disclosure.

FIG. 12 is a schematic diagram illustrating an exemplary electron beam tool with a beam-tilt function, consistent with embodiments of the present disclosure.

FIG. 13 is a process flowchart representing an exemplary method of imaging a sample using a tilted electron beam in an electron beam tool with a beam-tilt function, consistent with embodiments of the present disclosure.

FIG. 14 is a process flowchart representing an exemplary method of imaging a sample using a tilted electron beam in an electron beam tool with a beam-tilt function, consistent with embodiments of the present disclosure.

FIG. 15 is a process flowchart representing an exemplary method of imaging a sample using a tilted electron beam in an electron beam tool with a beam-tilt function, consistent with embodiments of the present disclosure.

FIG. 16 is a process flowchart representing an exemplary method of imaging a sample using a tilted electron beam in an electron beam tool with a beam-tilt function, consistent with embodiments of the present disclosure.

FIG. 17 is a process flowchart representing an exemplary method of imaging a sample using a tilted electron beam in an electron beam tool with a beam-tilt function, consistent with embodiments of the present disclosure.

FIGS. 18a-18d are schematic diagrams illustrating an exemplary range of beam-tilt angle for imaging contact holes in a device, consistent with embodiments of the present disclosure.

FIG. 19 is a schematic diagram illustrating exemplary feed-back and feed-forward data flow paths to and from a charged-particle beam apparatus, consistent with embodiments of the present disclosure.

FIG. 20 is a process flowchart representing an exemplary method of imaging a sample using a tilted charged-particle beam in an electron beam tool with a beam-tilt function, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC, thereby rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning electron microscope (SEM). An SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur.

Inspection of sidewall structures of a FinFET (Fin Field Effect Transistor), or underlying structures of high-aspect ratios such as deep vias or tilted contact holes, using a primary electron beam with vertical incidence may be challenging as well as misleading. One of several techniques to inspect such 3D structures includes tilting the incident electron beam to access underlying structures or hard-to-probe areas. The degree of tilt of an incident electron beam on a surface may vary based on the tool design, material being investigated, structures, desired analysis, or the like. While tilting the beam may be beneficial in some applications, it may offer significant challenges related to image resolution and throughput. For example, one or more beam deflectors employed to tilt the incident beam and the tilted beam trajectory through the objective lens may introduce aberrations of the charged-particle beam, and resultantly negatively impact the image resolution and throughput.

One of several desirable features in a wafer inspection tool or a metrology tool may include the flexibility of the tool to inspect simple and complex structures while maintaining the image resolution and throughput. In a vertical incidence mode of operation, high image resolution may be obtained, for example, by minimizing the working distance. The short working distance may reduce on-axis aberrations and allow a small spot size on the sample surface, thereby enhancing image resolution. However, in the tilted-beam mode, the objective lens may be placed farther away from the sample to accommodate one or more beam deflectors, thus increasing the working distance. The large working distance may increase on-axis aberrations, and additionally, the primary electron beam may not pass through the optical axis of the objective lens, introducing larger off-axis aberrations, causing the image resolution to deteriorate. Furthermore, it may be beneficial to maintain the probe spot position to avoid re-aligning the FOV while switching between vertical incidence and tilted-beam modes of operation.

Some embodiments of the present disclosure are directed to systems and methods of imaging a sample using a tilted beam. The method may include deflecting, using a first beam deflector, a primary electron beam comprising a plurality of electrons away from the primary optical axis. A second deflector may be used to deflect the deflected the primary electron beam back towards the primary optical axis such that it passes through an adjusted optical axis of the objective lens. A location of the optical axis of the objective lens may be adjusted by applying an electrical signal to a third deflector located on the objective lens. The ability to adjust the position of the optical axis of the objective lens may allow the primary electron beam to pass through the objective lens undeflected and to substantially coincide with the primary optical axis on the sample. The working distance may be minimized by placing the objective lens immediately upstream from the sample and also close to the sample.

Some embodiments of the present disclosure may be directed to apparatuses and methods of imaging a sample using a tilted charged-particle beam. The charged-particle beam apparatus may include a charged-particle source such as, but not limited to, an electron source and a deflector located substantially at a principal plane of an objective lens and configured to deflect the electron beam such that the electron beam lands on a sample surface at a beam-tilt angle. The apparatus may further include a controller configured to adjust an electrical signal applied to the deflector to cause an adjustment of the beam-tilt angle and determine a characteristic of a feature being imaged. The feature may comprise a high aspect ratio contact hole, and a characteristic of the feature may comprise a tilt angle of the contact hole. The adjustment of the beam-tilt angle may be based on a predetermined dimension of the feature such as, but not limited to, a top critical dimension, a bottom critical dimension, or an overlay between the top and the bottom critical dimension. The controller may be further configured to associate the adjusted beam-tilt angle with the corresponding feature to enhance traceability of tilt angle of individual features and local tilt uniformity of a plurality of features on the sample.

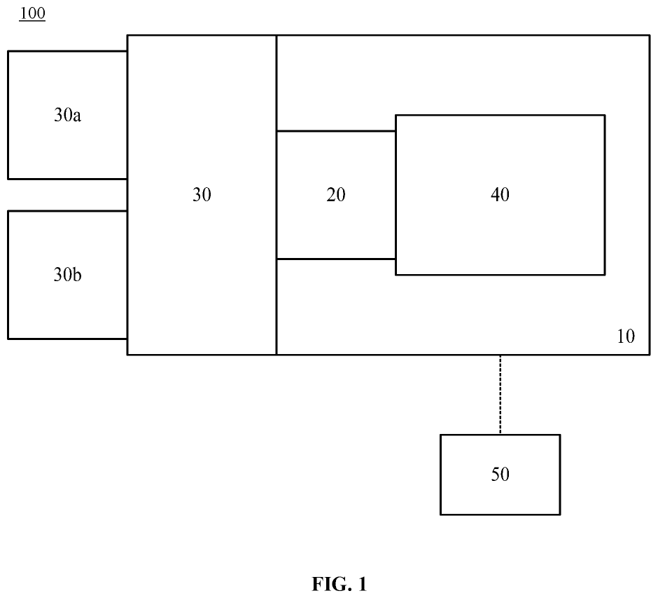

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C. Reference is now made to FIG. 1, which illustrates an exemplary electron beam inspection

(EBI) system 100 consistent with embodiments of the present disclosure. As shown in FIG. 1, charged particle beam inspection system 100 includes a main chamber 10, a load-lock chamber 20, an electron beam tool 40, and an equipment front end module (EFEM) 30. Electron beam tool 40 is located within main chamber 10. While the description and drawings are directed to an electron beam, it is appreciated that the embodiments are not used to limit the present disclosure to specific charged particles.

EFEM 30 includes a first loading port 30a and a second loading port 30b. EFEM 30 may include additional loading port(s). First loading port 30a and second loading port 30b receive wafer front opening unified pods (FOUPs) that contain wafers (e.g., semiconductor wafers or wafers made of other material(s)) or samples to be inspected (wafers and samples are collectively referred to as “wafers” hereafter). One or more robot arms (not shown) in EFEM 30 transport the wafers to load-lock chamber 20.

Load-lock chamber 20 is connected to a load/lock vacuum pump system (not shown), which removes gas molecules in load-lock chamber 20 to reach a first pressure below the atmospheric pressure. After reaching the first pressure, one or more robot arms (not shown) transport the wafer from load-lock chamber 20 to main chamber 10. Main chamber 10 is connected to a main chamber vacuum pump system (not shown), which removes gas molecules in main chamber 10 to reach a second pressure below the first pressure. After reaching the second pressure, the wafer is subject to inspection by electron beam tool 40. In some embodiments, electron beam tool 40 may comprise a single-beam inspection tool. In other embodiments, electron beam tool 40 may comprise a multi-beam inspection tool.

Controller 50 may be electronically connected to electron beam tool 40 and may be electronically connected to other components as well. Controller 50 may be a computer configured to execute various controls of charged particle beam inspection system 100. Controller 50 may also include processing circuitry configured to execute various signal and image processing functions. While controller 50 is shown in FIG. 1 as being outside of the structure that includes main chamber 10, load-lock chamber 20, and EFEM 30, it is appreciated that controller 50 can be part of the structure.

While the present disclosure provides examples of main chamber 10 housing an electron beam inspection system, it should be noted that aspects of the disclosure in their broadest sense, are not limited to a chamber housing an electron beam inspection system. Rather, it is appreciated that the foregoing principles may be applied to other chambers as well.

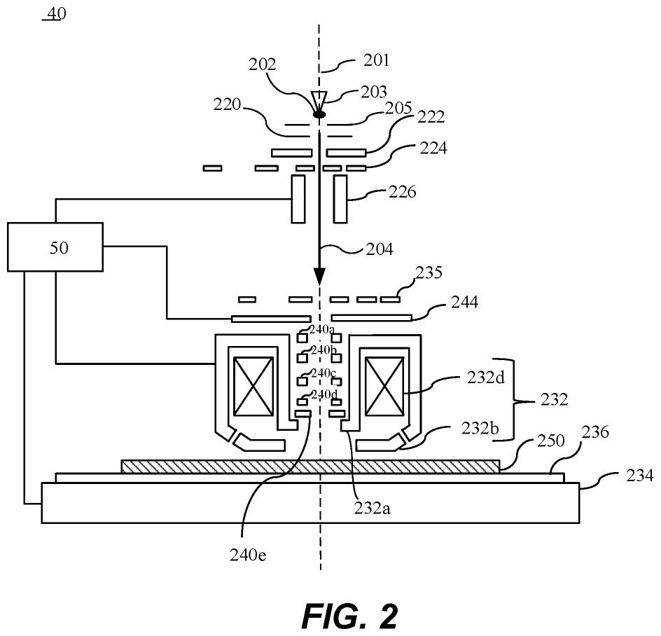

Reference is now made to FIG. 2, which illustrates a schematic diagram illustrating an exemplary configuration of electron beam tool 40 that can be a part of the exemplary charged particle beam inspection system 100 of FIG. 1, consistent with embodiments of the present disclosure. Electron beam tool 40 (also referred to herein as apparatus 40) may comprise an electron emitter, which may comprise a cathode 203, an extractor electrode 205, a gun aperture 220, and an anode 222. Electron beam tool 40 may further include a Coulomb aperture array 224, a condenser lens 226, a beam-limiting aperture array 235, an objective lens assembly 232, and an electron detector 244. Electron beam tool 40 may further include a sample holder 236 supported by motorized stage 234 to hold a sample 250 to be inspected. It is to be appreciated that other relevant components may be added or omitted, as needed.

In some embodiments, electron emitter may include cathode 203, an anode 222, wherein primary electrons can be emitted from the cathode and extracted or accelerated to form a primary electron beam 204 that forms a primary beam crossover 202. Primary electron beam 204 can be visualized as being emitted from primary beam crossover 202.

In some embodiments, the electron emitter, condenser lens 226, objective lens assembly 232, beam-limiting aperture array 235, and electron detector 244 may be aligned with a primary optical axis 201 of apparatus 40. In some embodiments, electron detector 244 may be placed off primary optical axis 201, along a secondary optical axis (not shown).

Objective lens assembly 232, in some embodiments, may comprise a modified swing objective retarding immersion lens (SORIL), which includes a pole piece 232a, a control electrode 232b, a beam manipulator assembly comprising deflectors 240a, 240b, 240d, and 240e, and an exciting coil 232d. In a general imaging process, primary electron beam 204 emanating from the tip of cathode 203 is accelerated by an accelerating voltage applied to anode 222. A portion of primary electron beam 204 passes through gun aperture 220, and an aperture of Coulomb aperture array 224, and is focused by condenser lens 226 so as to fully or partially pass through an aperture of beam-limiting aperture array 235. The electrons passing through the aperture of beam-limiting aperture array 235 may be focused to form a probe spot on the surface of sample 250 by the modified SORIL lens and deflected to scan the surface of sample 250 by one or more deflectors of the beam manipulator assembly. Secondary electrons emanated from the sample surface may be collected by electron detector 244 to form an image of the scanned area of interest. In objective lens assembly 232, exciting coil 232d and pole piece 232a may generate a

magnetic field. A part of sample 250 being scanned by primary electron beam 204 can be immersed in the magnetic field and can be electrically charged, which, in turn, creates an electric field. The electric field may reduce the energy of impinging primary electron beam 204 near and on the surface of sample 250. Control electrode 232b, being electrically isolated from pole piece 232a, may control, for example, an electric field above and on sample 250 to reduce aberrations of objective lens assembly 232 and control focusing situation of signal electron beams for high detection efficiency, or avoid arcing to protect sample. One or more deflectors of beam manipulator assembly may deflect primary electron beam 204 to facilitate beam scanning on sample 250. For example, in a scanning process, deflectors 240a, 240b, 240d, and 240e can be controlled to deflect primary electron beam 204, onto different locations of top surface of sample 250 at different time points, to provide data for image reconstruction for different parts of sample 250. It is noted that the order of 240a-e may be different in different embodiments.

Backscattered electrons (BSEs) and secondary electrons (SEs) can be emitted from the part of sample 250 upon receiving primary electron beam 204. A beam separator can direct the secondary or scattered electron beam(s), comprising backscattered and secondary electrons, to a sensor surface of electron detector 244. The detected secondary electron beams can form corresponding beam spots on the sensor surface of electron detector 244. Electron detector 244 can generate signals (e.g., voltages, currents) that represent the intensities of the received secondary electron beam spots, and provide the signals to a processing system, such as controller 50. The intensity of secondary or backscattered electron beams, and the resultant secondary electron beam spots, can vary according to the external or internal structure of sample 250. Moreover, as discussed above, primary electron beam 204 can be deflected onto different locations of the top surface of sample 250 to generate secondary or scattered electron beams (and the resultant beam spots) of different intensities. Therefore, by mapping the intensities of the secondary electron beam spots with the locations of sample 250, the processing system can reconstruct an image that reflects the internal or external structures of wafer sample 250.

In some embodiments, controller 50 may comprise an image processing system that includes an image acquirer (not shown) and a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detector 244 of apparatus 40 through a medium such as an electrical conductor, optical fiber cable, portable storage media, IR, Bluetooth, internet, wireless network, wireless radio, among others, or a combination thereof. In some embodiments, the image acquirer may receive a signal from electron detector 244 and may construct an image. The image acquirer may thus acquire images of regions of sample 250. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, controller 50 may include measurement circuitries (e.g., analog-to-digital converters) to obtain a distribution of the detected secondary electrons and backscattered electrons. The electron distribution data collected during a detection time window, in combination with corresponding scan path data of a primary beam 204 incident on the sample (e.g., a wafer) surface, can be used to reconstruct images of the wafer structures under inspection. The reconstructed images can be used to reveal various features of the internal or external structures of sample 250, and thereby can be used to reveal any defects that may exist in the wafer.

In some embodiments, controller 50 may control motorized stage 234 to move sample 250 during inspection. In some embodiments, controller 50 may enable motorized stage 234 to move sample 250 in a direction continuously at a constant speed. In other embodiments, controller 50 may enable motorized stage 234 to change the speed of the movement of sample 250 over time depending on the steps of scanning process.

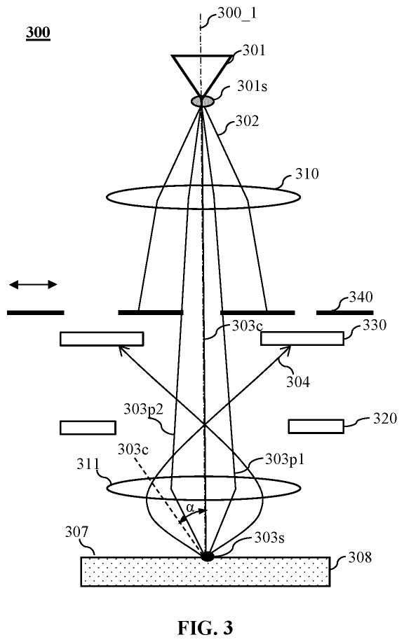

Reference is now made to FIG. 3, which is a schematic illustration of an exemplary electron beam tool 300. Electron beam tool 300 (also referred to herein as apparatus 300) may be used as a metrology, an inspection, or a review tool configured to inspect features including, but not limited to, contact holes, tilted contact holes, underlying structures in a 3D NAND device, high-aspect ratio structures, among other things. Apparatus 300 may be configurable to tilt a primary electron beam at a tilting angle α with respect to the surface normal, using one or more beam deflectors of a scanning deflection unit 320.

Apparatus 300 may comprise an electron source 301, a condenser lens 310, an objective lens 311, scanning deflection unit 320, a beam-limit aperture array 340, and a signal electron detector 330. In some embodiments, the signal electrons may be detected using one or more in-lens detectors (such as signal electron detector 330) located inside the electro-optic column of a SEM and may be arranged rotationally symmetric around the primary optical axis (e.g., primary optical axis 300_1). In some embodiments, it may also be referred to as upper detector. Primary electrons can be emitted from a cathode of electron source 301 and extracted or accelerated to form a primary electron beam 302 that forms a primary beam crossover (virtual or real) 301s. Primary electron beam 302 may comprise a plurality of electrons that can be visualized as being emitted from primary beam crossover 301s along a primary optical axis 300_1. It is to be appreciated that relevant components may be added or omitted or reordered, as appropriate.

In currently existing SEMs, as shown in FIG. 3, primary electron beam 302 may be emitted from electron source 301 and accelerated to a higher energy by an anode. A gun aperture may limit the current of primary electron beam 302 to a desired value. Primary electron beam 302 may be focused by condenser lens 310 and objective lens 311 to form a probe spot 303s on a surface 307 of a sample 308. The focusing power of condenser lens 310 and the opening size of an aperture of beam-limit aperture array 340 may be selected to get a desired probe current and make the probe spot size as small as possible. To obtain small spot sizes over a large range of probe currents, beam-limit aperture array 340 may comprise multiple apertures having various sizes. An aperture of beam-limiting aperture array 340 may be configured to generate an electron beam comprising an on-axis chief ray 303c passing through the aperture center and margin rays 303p1 and 303p2 passing through the aperture edge. The aperture of beam-limiting aperture array 340 may block peripheral electrons of primary electron beam 302, based on a desired probe current or a probe spot size. One or more deflectors of scanning deflection unit 320 may be configured to deflect primary electron beam 302 to scan a desired area on the surface of sample 308. As shown in FIG. 3, interaction of primary electron beamlet with sample 308 may generate a signal electron beam 304 comprising SEs and BSEs. Secondary electrons may be identified as signal electrons with low emission energies, and backscattered electrons may be identified as signal electrons with high emission energies.

Inspection of sidewall structures of a FinFET (Fin Field Effect Transistor), or underlying high-aspect ratio structures such as deep vias or tilted contact holes using a primary electron beam with vertical incidence may be challenging. In the context of this disclosure, “vertical incidence” refers to the incidence of a primary electron beam substantially parallel to a surface normal of a sample. The term “substantially parallel,” as used herein, refers to a substantially parallel orientation, for example, of an electron beam with respect to a reference axis, wherein an angle between the electron beam and the reference axis may be in a range of 0° to 0.2°. One of several ways to inspect such 3D structures may include tilting the incident electron beam with respect to the surface normal. The degree of tilt of an incident electron beam on a sample surface is referred to as the beam tilting angle, or beam-tilt angle α. In some applications, beam-tilt angles up to 30° may be used to obtain relevant information, or based on topography or density of structures. As an illustrative aid, FIG. 3 illustrates an imaginary tilted primary electron beam by its chief ray 303c (represented by a dashed line) incident on surface 307 at a beam-tilt angle α with respect to a surface normal such as, for example, parallel to primary optical axis 300_1. However, tilting the incident electron beam or the primary electron beam may, for example, cause aberrations of the primary electron beam such as spherical aberration, chromatic aberrations, astigmatism, coma and field-curvature aberrations, among other things, negatively affecting the image resolution and inspection throughput.

In currently existing SEM-based wafer inspection techniques, a focused primary electron beam may be scanned over a region of interest of a sample. The region of interest may comprise an underlying sub-surface structure, a defect, a node, a topographical feature, or the like. The scanned region of interest may form the field-of-view (FOV) of the sample. Enabling a SEM with beam-tilting function may present challenges including, but not limited to, maintaining image resolution over the FOV, maintaining beam-tilt angles over the FOV, or maintaining the alignment of the center of the FOV when the incident electron beam is tilted compared to the center of the FOV in a vertical incidence scenario. Some embodiments in the present disclosure disclose a method or an apparatus configured to perform the beam-tilt function while reducing off-axis aberrations, maintaining image resolution, or maintaining overall throughput.

As used in the context of this disclosure, “downstream” refers to a direction along the path of a primary electron beam (e.g., primary electron beam 302 of FIG. 3) starting from the electron source (e.g., electron source 301 of FIG. 3) towards the sample (e.g., sample 308 of FIG. 3). With reference to positioning of an element of a charged-particle beam apparatus (e.g., apparatus 300 of FIG. 3), “downstream” may refer to a position of an element located below or after another element, along the path of primary electron beam starting from the electron source, and “immediately downstream” refers to a position of a second element below or after a first element along the path of primary electron beam 302 such that there are no other active elements between the first and the second element. As used in the context of this disclosure, “upstream” may refer to a position of an element located above or before another element, along the path of primary electron beam starting from the electron source, and “immediately upstream” refers to a position of a second element above or before a first element along the path of primary electron beam 302 such that there are no other active elements between the first and the second element. As used herein, “active element” may refer to any element or component, the presence of which may modify the electromagnetic field between the first and the second element, either by generating an electric field, a magnetic field, or an electromagnetic field.

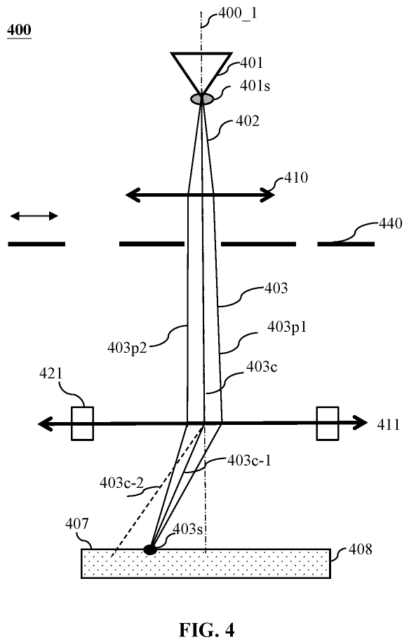

Reference is now made to FIG. 4, which illustrates an exemplary electron beam tool 400 (also referred to as apparatus 400) with beam-tilt function, analogous to electron beam tool 300, consistent with embodiments of the present disclosure. Apparatus 400 may comprise an electron source 401, a condenser lens 410, a beam-limit aperture array 440, a beam deflector 421, and an objective lens 411. It is to be appreciated that beam deflector 421 may be a stand-alone beam deflector or a part of a scanning deflection unit (e.g., scanning deflection unit 320 of FIG. 3). Objective lens 411 may be substantially similar or may perform substantially similar functions as objective lens 311 of FIG. 3.

A portion of primary electron beam 402 generated from electron source 401 may be focused using condenser lens 410 so as to fully or partially pass through an aperture of beam-limit aperture array 440 to form an electron beam 403. The electrons passing through the aperture of beam-limiting aperture array 440 may be focused to form probe spot 403s on surface 407 of sample 408 by objective lens 411 and deflected to scan the surface of sample 408 by beam deflector 421. Electron beam 403 may comprise an on-axis chief ray 403c and off-axis margin rays 403p1 and 403p2, for example.

In some embodiments, beam deflector 421 may be configured to deflect electron beam 403 away from primary optical axis 400_1 such that on-axis chief ray 403c is incident on surface 407 at a beam-tilt angle with respect to a surface normal of sample 408. The beam-tilt angle, also referred to herein as the tilt angle of incidence, refers to the angle between a chief ray of the incident primary electron beam and a surface normal. In some embodiments, the beam-tilt angle may be in a range of 5°-40°. In some embodiments, the beam-tilt angle may be less than 40°, or less than 30°, or less than 20°, or less than 10°, or less than 5°. It is appreciated that the beam-tilt angle may vary based on the application, sample, desired analysis, inspection tool capabilities, among other things.

In some embodiments, beam deflector 421 may be configured to deflect primary electron beam 403 away from primary optical axis 400_1 based on an electrical excitation signal comprising a static component and a dynamic component. The electrical excitation signal may comprise, for example, an AC voltage signal. As an example, an amplitude of the electrical excitation signal may be 100±20 V, where 100 V comprises the amplitude of the static component and 20 V comprises the amplitude of the dynamic component. The direction and degree of the tilt angle may be adjusted by adjusting the polarity and amplitude of the static component, and the size and orientation of scanning field of view (FOV) may be adjusted by adjusting the polarity and amplitude of the dynamic component. The static component of the electrical excitation signal, when applied, may cause beam deflector 421 to deflect on-axis chief ray 403c at a desired beam-tilt angle. The dynamic component of the electrical excitation signal, when applied, may cause beam deflector 421 to scan on-axis chief ray 403c on surface 407 to obtain a desired field-of-view. As illustrated in FIG. 4, chief ray 403c-2 represents a scanned chief ray incident on surface 407 of sample 408.

Beam deflector 421 may be located substantially at objective lens 411. In some embodiments, the deflection field of beam deflector 421 substantially overlaps the lens field of objective lens 411. Objective lens 411 may be configured to focus primary electron beam 403 with chief ray 403c-1 deflected by the static component of an electrical excitation signal applied to beam deflector 421 on to surface 407 of sample 408 and form probe spot 403s at an off-axis location away from primary optical axis 400_1. Objective lens 411 may be further configured to focus the primary electron beam 403 with chief ray 403c-2 deflected by both of the static and dynamic components on to surface 407 of sample 408. In some embodiments, the position of probe spot 403s, when only the static component is applied, is the geometric center of the FOV, and the beam-tilt angles may be different over the FOV. In the exemplary configuration of apparatus 400, the working distance may be minimized by placing objective lens 411 immediately upstream of sample 408, thereby reducing the aberrations and enhancing image resolution while tilting the incident electron beam and scanning the sample with a tilted incident electron beam. In apparatus 400, placing beam deflector 421 such that the deflection field substantially overlaps with the lens field of objective lens 411, may allow the working distance to be reduced, thereby reducing the associated aberrations.

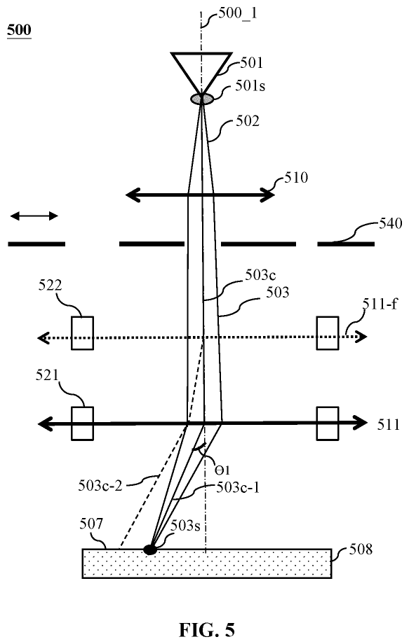

Reference is now made to FIG. 5, which illustrates an exemplary electron beam tool 500 (also referred to as apparatus 500) with beam-tilt function, analogous to electron beam tool 400, consistent with embodiments of the present disclosure. In comparison, a beam deflector 522 may be located between beam deflector 521 (analogous to beam deflector 421 of FIG. 4) and beam-limit aperture array 540 (analogous to beam-limit aperture array 440 of FIG. 4). It is to be appreciated that although analogous to apparatus 400, apparatus 500 may perform additional functions and components performing the additional functions may be added, removed, modified, or repurposed, as appropriate.

Beam deflector 521 may be configured to tilt electron beam 503 at a desired beam-tilt angle, and beam deflector 522 may be configured to scan electron beam 503 on surface 507 of sample 508 to form the FOV. For beam tilting, beam deflector 522 may be configured to allow electron beam 503 to pass through undeflected. Beam deflector 521 may be configured to deflect on-axis chief ray 503c away from primary optical axis 500_1 based on a static electrical excitation signal. On-axis chief ray 503c may be deflected at a deflection angle θ1 with respect to primary optical axis 500_1, forming deflected chief ray 503c-1. In some embodiments, objective lens 511 may be configured to focus the primary electron beam with deflected chief ray 503c-1 on to surface 507, forming an incident electron beamlet having a desired beam-tilt angle.

For beam scanning, beam deflector 522 may be configured to deflect on-axis chief ray 503c away from primary optical axis 500_1 based on a dynamic electrical excitation signal applied to beam deflector 522. Beam deflector 522 may be positioned to substantially overlap with front focal plane 511-f of objective lens 511. Because beam deflector 522 deflects chief ray 503c at front focal plane 511-f, the tilt angle of deflected chief ray 503c-2 is substantially similar to tilt angle of chief ray 503c-1. Beam deflector 521 may be configured to further deflect the deflected chief ray 503c forming chief ray 503c-2 away from primary optical axis 500_1 based on a static electrical excitation signal. In some embodiments, objective lens 511 may be configured to focus the primary electron beam with chief ray 503c-1 or 503c-2 on to surface 507, forming an incident electron beamlet having a desired beam-tilt angle of incidence. An adjustment of the dynamic electrical excitation signal may cause beam deflector 522 to adjust the deflection angle of on-axis chief ray 503c, and thereby cause scanning the region of interest and form the FOV. The tilt angle may be substantially similar across the FOV. It should be noted that although the tilt angle may be substantially similar, however, aberrations may be different across the FOV. The difference in aberrations across the FOV may be acceptable for small FOVs.

The electrical excitation signal may comprise a voltage signal having a static and a dynamic component. As an example, a static voltage signal of 100V may be applied to beam deflector 521 to tilt the beam at a desired tilt angle, and a dynamic voltage signal of ±20V may be applied to beam deflector 522 to scan the beam to form the FOV.

In some embodiments, beam deflector 522 may be located upstream of beam deflector 521 and may substantially overlap with front focal plane 511-f of objective lens 511. Placing beam deflector 522 substantially along front focal plane 511-f of objective lens 511 may allow maintaining the beam-tilt angles substantially uniform over the FOV. In the exemplary configuration of apparatus 500, the working distance may be minimized by placing objective lens 511 upstream of sample 508, thereby reducing the on-axis aberrations and enhancing image resolution while tilting the incident electron beam and scanning the sample over the FOV with the tilted incident electron beam and same beam-tilt angles.

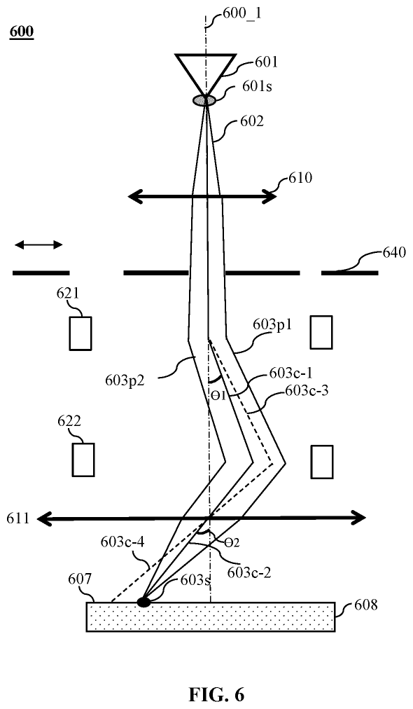

Reference is now made to FIG. 6, which illustrates an exemplary electron beam tool 600 (also referred to as apparatus 600) with beam-tilt function, analogous to electron beam tool 500, consistent with embodiments of the present disclosure. In comparison, a beam deflector 622 (analogous to beam deflector 522 of FIG. 5) may be located between beam deflector 621 and objective lens 611 (analogous to objective lens 511 of FIG. 5). It is to be appreciated that although analogous to apparatus 500, apparatus 600 may perform additional functions and components performing the additional functions may be added, removed, modified, or repurposed, as appropriate.

In some embodiments, both beam deflectors 621 and 622 may be configured to tilt and scan electron beam 603 to form the FOV on sample 608 based on applied electrical excitation signals. Beam deflector 621, located immediately downstream or downstream of beam-limit aperture array 640, may be configured to deflect electron beam 603 away from primary optical axis 600_1 at a first deflection angle θ1 to form deflected chief ray 603c-1 based on a static component of an electrical excitation signal applied to beam deflector 621. Beam deflector 622, located immediately downstream or downstream of beam deflector 621 may be configured to deflect deflected chief ray 603c-1 towards primary optical axis 600_1 at a second deflection angle θ2 to form deflected chief ray 603c-2 based on a static component of an electrical excitation signal applied to beam deflector 622. The deflection angles refer to the angle between the deflected chief ray such as 603c-1-603c-4 with respect to primary optical axis 600_1. In some embodiments, adjustment of the static component of the electrical excitation signal may cause deflected chief ray 603c-2 to pass through the wobbling center of objective lens 611 and form probe spot 603s on surface of sample 608 away from primary optical axis 600_1. If a beam passes through a wobbling center of a lens, it will keep its exit direction same when the lens excitation is slightly changed. This can ensure the beam has minimum off-axis aberrations due to the lens.

In some embodiments, for beam scanning over the FOV, beam deflector 621 may be further configured to deflect electron beam 603 away from primary optical axis 600_1 at a third deflection angle θ3 (not shown) to form deflected chief ray 603c-3 based on a dynamic component of an electrical excitation signal applied to beam deflector 621. Beam deflector 622 may be further configured to deflect deflected chief ray 603c-3 towards primary optical axis 600_1 at a fourth deflection angle θ4 to form deflected chief ray 603c-4 based on a dynamic component of an electrical excitation signal applied to beam deflector 622. In some embodiments, adjustment of the dynamic component of the electrical excitation signal may cause deflected chief ray 603c-4 to pass through the wobbling center of objective lens 611 and land on surface 607 of sample 608 away from primary optical axis 600_1 and away from probe spot 603s.

As used herein, “optical axis” of an objective lens refers to an imaginary axis which passes through the geometrical center of the objective lens. The optical axis may pass through the wobbling center of objective lens. Allowing one or more chief rays such as 603c-2 and 603c-4 to pass through the wobbling center of objective lens 611 may minimize the off-axis aberrations caused due to objective lens 611. In the exemplary configuration of apparatus 600, the working distance may be minimized by placing objective lens 611 immediately upstream or upstream of sample 608, thereby reducing the off-axis aberrations and enhancing image resolution while tilting the incident electron beam and scanning the sample over the FOV with the tilted incident electron beam.

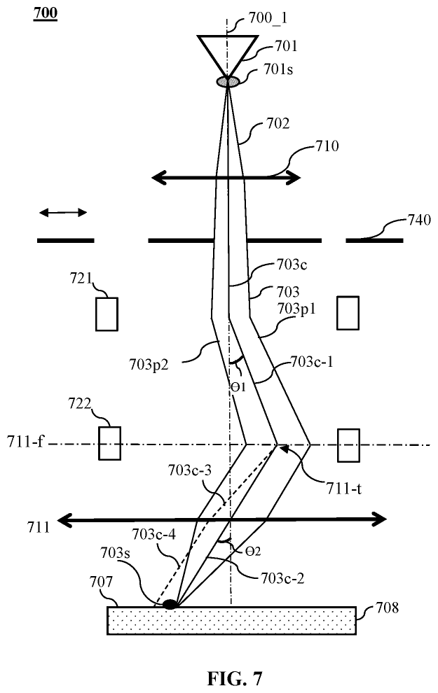

Reference is now made to FIG. 7, which illustrates an exemplary electron beam tool 700 (also referred to as apparatus 700) with beam-tilt function, analogous to electron beam tool 600, consistent with embodiments of the present disclosure. In comparison, beam deflector 722 (analogous to beam deflector 622 of FIG. 6) may be located substantially at a front focal plane 711-f of objective lens 711 (analogous to objective lens 611 of FIG. 6). It is to be appreciated that although analogous to apparatus 600, apparatus 700 may perform additional functions and components performing the additional functions may be added, removed, modified, or repurposed, as appropriate.

Beam deflector 721 may be configured to tilt electron beam 703 at a desired beam-tilt angle, and beam deflector 722 may be configured to tilt and scan electron beam 703 on surface 707 of sample 708 to form the FOV. For beam-tilting, beam deflector 721 may be configured to deflect on-axis chief ray 703c away from primary optical axis 700_1 based on a static electrical excitation signal. On-axis chief ray 703c may be deflected at a deflection angle θ1 with respect to primary optical axis 700_1, forming deflected chief ray 703c-1. Beam deflector 722, located substantially along front focal plane 711-f of objective lens 711 may be configured to deflect deflected chief ray 703c-1 towards primary optical axis 700_1 at a second deflection angle θ2 to form deflected chief ray 703c-2 based on a static component of an electrical excitation signal applied to beam deflector 722. Deflected chief ray 703c-1 may pass through the front focal plane of objective lens 711 at an off-axis location 711-t. In some embodiments, objective lens 711 may be configured to focus the primary electron beam with deflected chief ray 703c-2 on to surface 707 at a desired beam-tilt angle of incidence. Deflected chief ray 703c-2 may pass through the wobbling center of objective lens 711, forming a desired beam-tilt angle of incidence. In some embodiments, the second deflection angle θ2 may comprise the beam-tilt angle of incidence.

For beam scanning, beam deflector 722 may be configured to deflect chief ray 703c-1 back towards primary optical axis 700_1, forming 703c-3 at a deflection angle different than the deflection angle of 703c-2, based on a dynamic electrical excitation signal applied to beam deflector 722. In some embodiments, objective lens 711 may be configured to focus the primary electron beam with deflected chief ray 703c-3 on to surface 507. Chief ray 703c-3 may be deflected to form 703c-4 as it passes through objective lens 711, such that the beam-tilt angle of incidence formed by chief ray 703c-4 is substantially similar to the beam-tilt angle of incidence formed by chief ray 703c-2 with respect to surface normal. An adjustment of the dynamic electrical excitation signal may cause beam deflector 722 to adjust the deflection angle of chief ray 703c-3, and thereby scan the region of interest and form the FOV. In the exemplary configuration of apparatus 700, the working distance may be minimized by placing objective lens 711 immediately upstream of sample 708, thereby reducing the aberrations and enhancing image resolution while tilting the incident electron beam and scanning the sample over the FOV with the tilted incident electron beam and same tilted beam-tilt angles.

One of several desirable features in a wafer inspection or a metrology tool may include flexibility of the tool to inspect simple and complex structures while maintaining the image resolution and throughput. An inspection tool such as a SEM may be switched between a “vertical incidence mode” to a “tilted-beam mode” based on the application or the desired analysis. In a vertical incidence mode of operation, high image resolution may be obtained, for example, by minimizing the working distance. The short working distance may reduce on-axis aberrations, and allow a small spot size on the sample surface, thereby enhancing image resolution. However, in the tilted-beam mode, the objective lens may be placed farther away from the sample to accommodate one or more beam deflectors, thus increasing the working distance. The large working distance may introduce large aberrations, and additionally, the primary electron beam may not pass through the objective lens along the optical axis thereof, causing the image resolution to deteriorate. Furthermore, it may be beneficial to maintain the FOV center to avoid re-aligning the FOV while switching between vertical incidence and tilted-beam modes of operation. In vertical incidence mode of operation, FOV center may substantially coincide with the primary optical axis 800_1. In tilted-beam mode of operation, the FOV center may be at an off-axis location if no adjustment is used. As used herein, “off-axis location” indicates a location away from the primary optical axis. One of several ways to adjust the FOV center back to substantially coincide with the primary optical axis may include re-aligning the FOV in the tilted-beam mode. In practice, re-aligning the FOV may negatively impact the inspection throughput, among other issues. Thus, it may be desirable to maintain the FOV center aligned with the primary optical axis in vertical incidence as well as tilted-beam modes of operation. Therefore, it may be desirable to provide methods and systems configured to tilt the incident electron beam while maintaining the image resolution and high throughput by keeping FOV center unchanged.

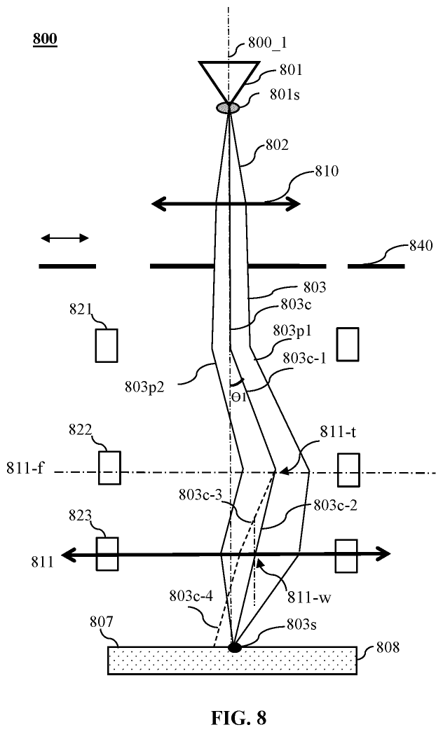

Reference is now made to FIG. 8, which illustrates an exemplary electron beam tool 800 (also referred to as apparatus 800) with beam-tilt function, consistent with embodiments of the present disclosure. In comparison, apparatus 800 may additionally comprise beam deflector 823 positioned to substantially overlap with objective lens 811. It is to be appreciated that although apparatus 800 is shown to use three deflectors, three or more deflectors may be employed, as appropriate.

Apparatus 800 may be configured to be used as an inspection tool, a review tool, or a metrology tool in a wafer processing facility such as a wafer FAB. Apparatus 800 may be configured to perform beam-tilting function to enable inspection of structures including deep holes, angled vias, side walls, or other high-aspect ratio features.

In “tilted-beam mode” of some embodiments, for beam-tilting, beam deflector 821 may be configured to deflect electron beam 803 away from primary optical axis 800_1 at a deflection angle θ1 with respect to primary optical axis 800_1 based on a static electrical excitation signal. On-axis chief ray 803c may be deflected at a deflection angle θ1 with respect to primary optical axis 800_1, forming deflected chief ray 803c-1. Beam deflector 822, located substantially along front focal plane 811-f of objective lens 811 may be configured to deflect deflected chief ray 803c-1 towards primary optical axis 800_1 at a second deflection angle θ2 (not shown) to form deflected chief ray 803c-2 based on a static component of an electrical excitation signal applied to beam deflector 822. Deflected chief ray 803c-1 may pass through front focal plane 811-f of objective lens 811 at an off-axis location 811-t.

If objective lens 811 is aligned with primary optical axis 800_1, the wobbling center of the objective lens 811 may substantially coincide with the primary optical axis 800_1.

In some embodiments, the wobbling center and the optical axis of objective lens 811 may be adjusted to an off-axis location based on an electrical excitation signal applied to beam deflector 823. The adjusted wobbling center 811-w of objective lens 811 may represent a zero-force location on the principal plane of objective lens 811. A charged-particle such as an electron passing through adjusted wobbling center 811-w may experience equal but opposite radial forces generated by beam deflector 823 and objective lens 811. The deflection field of beam deflector 823 may substantially overlap with field of objective lens 811. As illustrated in FIG. 8, deflected chief ray 803c-2 may pass through adjusted wobbling center 811-w. Beam deflectors 821, 822, and 823 may be configured to deflect primary electron beam 803 such that probe spot 803s coincides with primary optical axis 800_1. In some embodiments, objective lens 811 may be configured to focus deflected primary electron beam with chief ray 803c-2 on surface 807 of sample 808 forming probe spot 803s, which substantially coincides with primary optical axis 800_1 or may coincide with the FOV center of “vertical incidence mode”. An adjustment of a static component of an electrical excitation signal applied to beam deflector 823 may adjust the location of adjusted wobbling center 811-w.

In some embodiments, beam deflector 822, located substantially along front focal plane 811-f of objective lens 811 may be configured to deflect deflected chief ray 803c-1 towards primary optical axis 800_1 at a third deflection angle θ3 (not shown). For beam scanning, on-axis chief ray 803c-1 may be deflected towards primary optical axis 800_1 to form deflected chief ray 803c-3 based on a dynamic component of the electrical excitation signal applied to beam deflector 822. Objective lens 811 may be configured to focus the primary electron beam with deflected chief ray 803c-3 incident on surface 807 of sample 808. The chief ray 803c-4 of the focused primary electron beam landing on sample has a beam-tilt angle of incidence substantially similar to the beam-tilt angle of incidence of deflected chief ray 803c-2. In this configuration, the aberrations of objective lens 811 may be reduced by moving the wobbling center and the optical axis of objective lens 811 away from primary optical axis and letting primary electron beam 803 pass through the moved wobbling center as much as possible. However, the aberrations may be non-uniform over the FOV because deflected chief ray 803c-3 does not pass through wobbling center 811-w of objective lens 811 over the FOV.

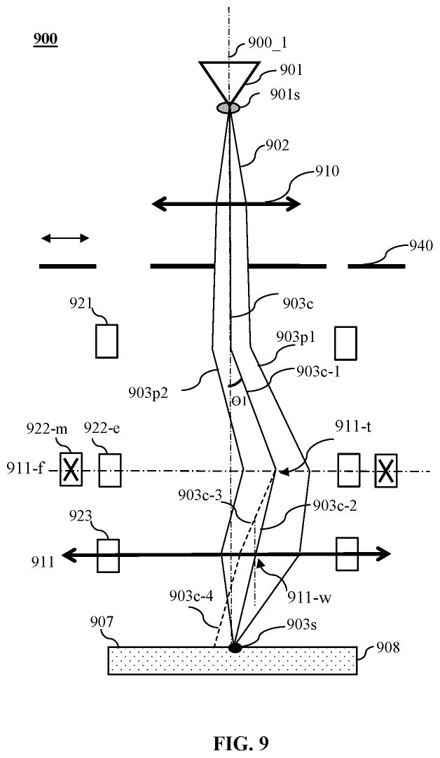

Reference is now made to FIG. 9, which illustrates an exemplary electron beam tool 900 (also referred to as apparatus 900) with beam-tilt function, analogous to electron beam tool 800, consistent with embodiments of the present disclosure. In comparison, beam deflector 922 may comprise an electrostatic deflector 922-e and a magnetic deflector 922-m. It is to be appreciated that although analogous to apparatus 800, apparatus 900 may perform substantially similar functions or additional functions and components performing the additional functions may be added, removed, modified, or repurposed, as appropriate.

Some of the challenges in designing an inspection tool or a metrology tool with beam-tilt functionality, compared to a vertical incidence inspection tool, may include, but are not limited to, deterioration of image resolution, non-uniform beam-tilt angles over the FOV, shifted FOV centers, among other things. As discussed earlier, increasing the working distance to accommodate one or more beam deflectors, among other things, may negatively impact the image resolution. A beam deflector driver including circuitry configured to supply static and dynamic components of an electrical excitation signal to the beam deflector(s) may also negatively impact the image resolution due to the high signal noise and bandwidth. Therefore, it may be desirable to provide methods and systems configured to tilt the incident electron beam while maintaining the image resolution and high throughput.

In some embodiments, apparatus 900 may comprise electrostatic deflector 922-e and magnetic deflector 922-m configured to scan incident electron beam 903 and tilt incident electron beam 903, respectively. In some embodiments, electrostatic deflector 922-e and magnetic deflector 922-m may be located substantially at the front focal plane 911-f of objective lens 911. Magnetic deflector 922-m may be configured to tilt electron beam 903 statically and electrostatic deflector 922-e may be configured to scan electron beam 903 dynamically to form the FOV. It is to be appreciated that apparatus 900 may perform beam-tilt functions substantially similar to the beam-tilt functions performed by apparatus 800 and may use substantially similar components.

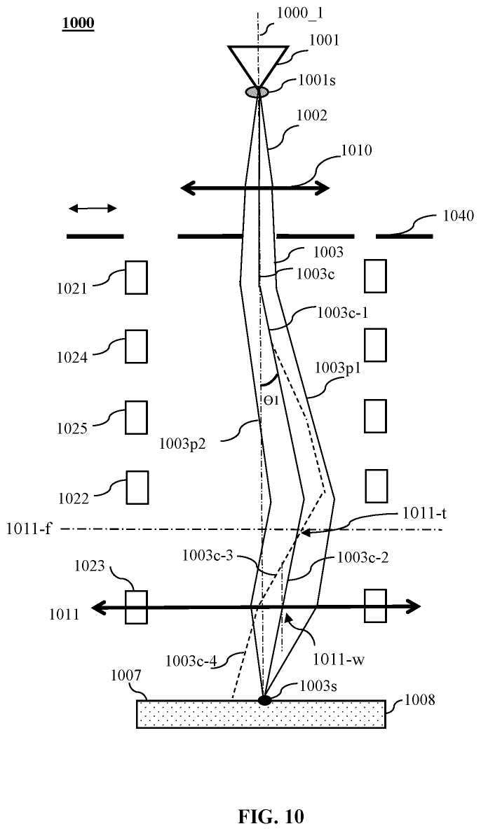

Reference is now made to FIG. 10, which illustrates an exemplary electron beam tool 1000 (also referred to as apparatus 1000) with beam-tilt function, analogous to electron beam tool 900, consistent with embodiments of the present disclosure. In comparison, apparatus 1000 may additionally comprise beam deflectors 1024 and 1025. It is to be appreciated that although analogous to apparatus 900, apparatus 1000 may perform substantially similar functions or additional functions and components performing the additional functions may be added, removed, modified, or repurposed, as appropriate.

In some embodiments, electron beam 1003 formed after passing through an aperture of beam-limit aperture array 1040 may comprise an on-axis chief ray 1003c and off-axis margin rays. Beam deflector 1021, located downstream or immediately downstream from beam-limit aperture array 1040, may be configured to deflect electron beam 1003 away from primary optical axis 1000_1 based on a static electrical excitation signal. On-axis chief ray 1003c may be deflected at a deflection angle θ1 with respect to primary optical axis 1000_1, forming deflected chief ray 1003c-1. Beam deflector 1022 may be configured to deflect deflected chief ray 1003c-1 towards primary optical axis 1000_1 based on a static electrical excitation signal, forming deflected chief ray 1003c-2 at a deflection angle θ2 (not shown) with respect to primary optical axis 1000_1. Beam deflector 1022 may be located upstream, or downstream, or at front focal plane 1011-f. Deflected chief ray 1003c-2 may pass through front focal plane 1011-f of objective lens 1011 at location 1011-t and adjusted wobbling center 1011-w. Beam deflector 1023 may be configured to adjust the wobbling center of objective lens 1011 to 1011-w. Primary electron beam with deflected chief ray 1003c-2, passing through adjusted wobbling center 1011-w may be focused by objective lens 1011 onto surface 1007 of sample 1008 at a first beam-tilt angle of incidence and form probe spot 1003s, which substantially coincides with primary optical axis 1000_1 or substantially coincides with the FOV center of “vertical incident mode”. Beam deflectors 1021, 1022, and 1023 may be configured such that probe spot 1003s substantially coincides with primary optical axis 1000_1 or may coincide with the FOV center of “vertical incidence mode”. In some embodiments, beam deflectors 1024 and 1025 may be configured to scan the

primary electron beam by further deflecting deflected chief ray 1003c-1 away from primary optical axis 1000_1 based on a dynamic electrical excitation signal. Beam deflector 1022, located downstream from beam deflectors 1024 and 1025, may be configured to further deflect the deflected chief ray 1003c-1 towards primary optical axis 1000_1, forming deflected chief ray 1003c-3 passing through the front focal plane 1011-f of objective lens 1011 at location 1011-t. Objective lens 1011 may be configured to focus the primary electron beam with deflected chief ray 1003c-3 on surface 1007 of sample 1008 at a second beam-tilt angle of incidence. In the exemplary configuration of apparatus 1000, the first and the second beam-tilt angles of incidence may be substantially uniform over the FOV. Further, the FOV center shift between tilted mode and vertical incidence mode may be minimum.

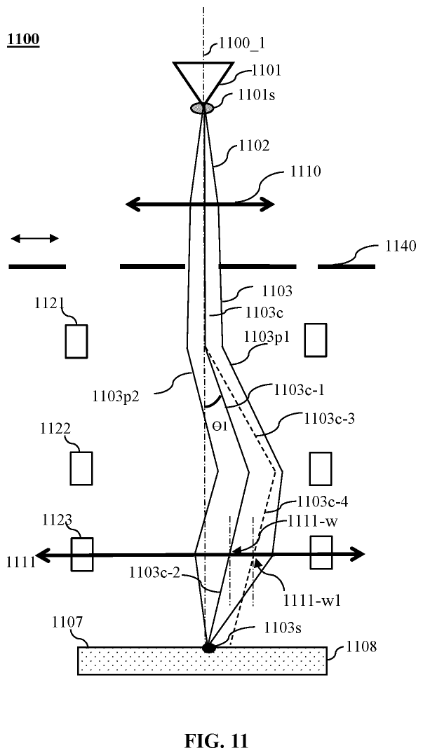

Reference is now made to FIG. 11, which illustrates an exemplary electron beam tool 1100 (also referred to as apparatus 1100) with beam-tilt function, analogous to electron beam tool 1000, consistent with embodiments of the present disclosure. In comparison, beam deflectors 1121, 1122, and 1123 may be configured to tilt and scan electron beam 1103. It is to be appreciated that although analogous to apparatus 800, apparatus 1100 may perform substantially similar functions or additional functions and components performing the additional functions may be added, removed, modified, or repurposed, as appropriate.

In addition to minimizing the on-axis aberrations by reducing the working distance, maintaining the probe spot along the primary optical axis to allow switching between vertical incidence and tilted beam incidence, and keeping the tilt angle of incidence uniform over the FOV, it may be desirable to keep the aberrations uniform over the FOV.

In some embodiments, for beam-tilting, beam deflector 1121 may be configured to deflect electron beam 1103 away from primary optical axis 1100_1 based on a static component of an electrical excitation signal applied to beam deflector 1121. On-axis chief ray 1103c may be deflected at a deflection angle θ1 with respect to primary optical axis 1100_1, forming deflected chief ray 1103c-1. Beam deflector 1122, located between objective lens 1111 and beam deflector 1121, may be configured to deflect deflected chief ray 1103c-1 towards primary optical axis 1100_1 at a second deflection angle θ2 (not shown) to form deflected chief ray 1103c-2 based on a static component of an electrical excitation signal applied to beam deflector 1122. Beam deflector 1123 located at objective lens 1111 may shift wobbling center of objective lens 1111 away from the primary optical axis to a first adjusted location 1111-w. Objective lens 1111 may focus the primary electron beam with deflected chief ray 1103c-2 onto surface 1107 of sample 1108 and forms probe spot 1103s. Deflected chief ray 1103c-2 may pass through adjusted wobbling center 1111-w of objective lens 1111 and lands on surface 1107 of sample 1108 with a first beam-tilt angle, and substantially coincides with primary optical axis 1100_1 on surface 1107 of sample 1108.

In some embodiments, for beam scanning, beam deflector 1121 may be configured to further deflect electron beam 1103 away from primary optical axis 1100_1 based on a dynamic component of an electrical excitation signal applied to beam deflector 1121. On-axis chief ray 1103c may be deflected at a deflection angle θ3 (not shown) with respect to primary optical axis 1100_1, forming deflected chief ray 1103c-3. Beam deflector 1122 may be configured to deflect deflected chief ray 1103c-3 towards primary optical axis 1100_1 at a deflection angle θ4 (not shown) to form deflected chief ray 1103c-4 based on a dynamic component of the electrical excitation signal applied to beam deflector 1122. Deflector 1123 may shift wobbling center of objective lens 1111 away from the primary optical axis to a second adjusted location 1111-w1. Objective lens 1111 may focus the primary electron beam with deflected chief ray 1103c-4 onto surface 1107 of sample 1108 and forms probe spot (not shown). Deflected chief ray 1103c-4 may pass through adjusted wobbling center 1111-w1 of objective lens 1111, and be incident on surface 1107 at a second beam-tilt angle substantially similar to the first beam-tilt angle.

In some embodiments, beam deflector 1123 may be configured to adjust the position of a wobbling center of objective lens 1111 based on an electrical excitation signal. A static component of the electrical excitation signal applied to beam deflector 1123 may adjust the position of wobbling center to the first adjusted wobbling center 1111-w, and a dynamic component of the electrical excitation signal applied to beam deflector 1123 may further adjust the position of wobbling center to the second adjusted wobbling center 1111-w1. In some embodiments, deflected chief ray 1103c-2 may pass through adjusted wobbling center 1111-w and deflected chief ray 1103c-4 may pass through adjusted wobbling center 1111-w1.

In some embodiments, each of the beam deflectors 1121, 1122, and 1123 may comprise an electrostatic deflector and a magnetic deflector (not shown), analogous to electrostatic deflector 922-e and magnetic deflector 922-m of apparatus 900. In some embodiments, one or more electrostatic deflectors may be configured to scan electron beam 1103 based on a dynamic excitation signal, and one or more magnetic deflectors may be configured to tilt electron beam 1103 based on a static excitation signal. The dynamic components of electrical excitation signals of beam deflectors 1121 and 1122 make deflected on-axis chief ray 1103c-4 to land on surface 1107 of sample 1108 with same incidence angle as 1103c-2.

In some embodiments, apparatus 1100 may comprise three or more beam deflectors. For example, one or more beam deflectors may be inserted between beam deflectors 1121 and 1122, analogous to beam deflectors 1024 and 1025 of apparatus 1000 shown in FIG. 10. In such a configuration, beam deflectors 1121 and 1122 may be configured to tilt electron beam 1103 based on static excitation signals, and the inserted beam deflectors may be configured to scan electron beam 1103.

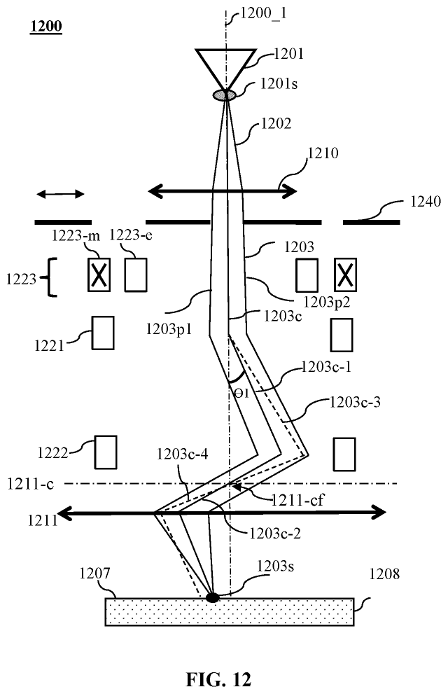

Reference is now made to FIG. 12, which illustrates an exemplary electron beam tool 1200 (also referred to as apparatus 1200) with beam-tilt function, analogous to electron beam tool 600, consistent with embodiments of the present disclosure. In comparison, apparatus 1200 may additionally include a dispersion compensator 1223 comprising an electrostatic deflector 1223-e and a magnetic deflector 1223-m. It is to be appreciated that although analogous to apparatus 600, apparatus 1200 may perform substantially similar functions or additional functions and components performing the additional functions may be added, removed, modified, or repurposed, as appropriate.

In some embodiments, dispersion compensator 1223 may be a Wien filter comprising electrostatic deflector 1223-e and magnetic deflector 1223-m, generating an electrostatic dipole field E1 and a magnetic dipole field B1 (both of which are not shown in FIG. 12). If both fields are applied such that the force exerted by electrostatic dipole field E1 on an electron of electron beam 1203 is equal in magnitude and opposite in direction to the force exerted on the electron by magnetic dipole field B1, electron beam 1203 can pass straight through dispersion compensator 1223 with zero deflection angles. This condition is referred to as the Wien condition. In practice, however, electron beam 1203 may comprise electrons at differing energy levels. Therefore, electrons of electron beam 1203 passing through dispersion compensation 1223 may not necessarily pass entirely straight through and may instead be deflected with small deflection angles. Accordingly, deflection angles of electrons in electron beam 1203 may be different, thereby causing dispersion to be generated in electron beam 1203. Although in some applications energy dispersion caused by dispersion compensator 1223 may be undesirable, however, it may be useful to compensate the off-axis chromatic aberration of objective lens 1211 in apparatus 1200.

In some embodiments, apparatus 1200 may comprise beam deflector 1221 configured to deflect electron beam 1203 away from primary optical axis 1200_1 based on a static component of an electrical excitation signal applied to beam deflector 1221. On-axis chief ray 1203c may be deflected at a deflection angle θ1 with respect to primary optical axis 1200_1 based on a static component of the electrical excitation signal, forming deflected chief ray 1203c-1. Beam deflector 1222, located immediately downstream from beam deflector 1221, may be configured to deflect deflected chief ray 1203c-1 towards primary optical axis 1200_1 at a deflection angle θ2 (not shown) to form deflected chief ray 1203c-2 based on a static component of an electrical excitation signal applied to beam deflector 1222. Deflected chief ray 1203c-2 may pass through a substantially coma-free point 1211-cf on a coma-free plane 1211-c of objective lens 1211. As used herein, the term “coma-free location” or “coma-free point” refers to a point of an objective lens at which minimum or substantially no coma is introduced in the electron beam passing through the objective lens. The coma-free point of the objective lens is a point of the objective lens at which the Fraunhofer condition is satisfied.

In some embodiments, the coma-free point 1211-cf of objective lens 1211 may be located substantially on primary optical axis 1200_1. The primary optical axis 1200_1 may correspond to an optical axis of objective lens 1211.

In some embodiments, for beam-scanning, beam deflector 1221 may be configured to deflect electron beam 1203 away from primary optical axis 1200_1 based on a dynamic component of the electrical excitation signal applied to beam deflector 1221. On-axis chief ray 1203c may be deflected at a deflection angle θ3 with respect to primary optical axis 1200_1 based on the dynamic component of the electrical excitation signal, forming deflected chief ray 1203c-3. Beam deflector 1222 may be configured to deflect deflected chief ray 1203c-3 towards primary optical axis 1200_1 at a deflection angle θ4 (not shown) to form deflected chief ray 1203c-4 based on a dynamic component of the electrical excitation signal applied to beam deflector 1222. Deflected chief ray 1203c-4 may also pass through coma-free point 1211-cf on coma-free plane 1211-c of objective lens 1211, thus reducing or minimizing the coma-aberration.

In some embodiments, coma-free plane 1211c of objective lens 1211 may be formed immediately downstream from beam deflector 1222 and upstream of objective lens 1211. The electrical excitation of objective lens 1211 may be adjusted to compensate the field-curvature. Apparatus 1200 may include a stigmator (not shown) or a multipole lens configured to compensate the astigmatism. In some embodiments, beam deflector 1222 may be configurable to be used as a deflector as well as a stigmator.

In some embodiments, each of the beam deflectors 1221 and 1222 may comprise an electrostatic deflector and a magnetic deflector (not shown), analogous to electrostatic deflector 922-e and magnetic deflector 922-m of apparatus 900. In some embodiments, one or more electrostatic deflectors may be configured to scan electron beam 1203 based on a dynamic excitation signal, and one or more magnetic deflectors may be configured to tilt electron beam 1203 based on a static excitation signal.

In some embodiments, apparatus 1200 may comprise three or more beam deflectors. For example, one or more beam deflectors may be inserted between beam deflectors 1221 and 1222, analogous to beam deflectors 1024 and 1025 of apparatus 1000 shown in FIG. 10. In such a configuration, beam deflectors 1221 and 1222 may be configured to tilt based on static excitation signals, and the one or more beam deflectors may be configured to scan the tilted primary electron beam to form the FOV based on dynamic excitation signals thereof.

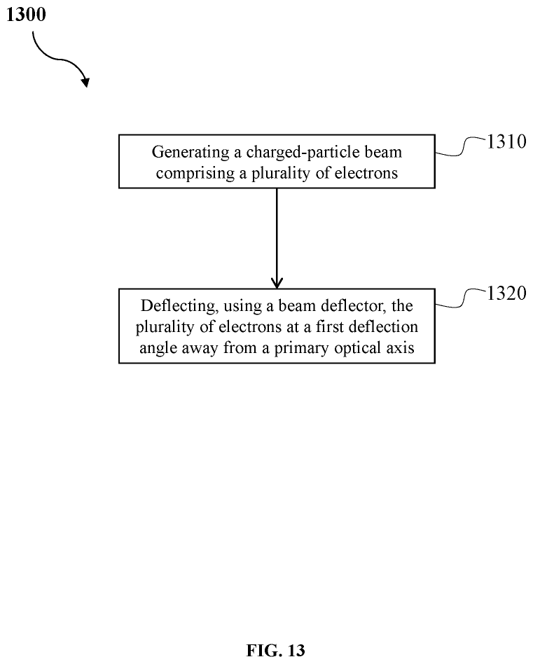

Reference is now made to FIG. 13, which illustrates a process flowchart representing an exemplary method 1300 for imaging a sample using a tilted electron beam in an electron beam tool with a beam-tilt function, consistent with embodiments of the present disclosure. Method 1300 may be performed by controller 50 of EBI system 100, as shown in FIG. 1, for example. Controller 50 may be programmed to implement one or more steps of method 1300. For example, controller 50 may instruct a module of a charged particle beam apparatus to activate a charged-particle source to generate charged particle beam (e.g., electron beam) and carry out other functions.

In step 1310, a charged-particle source (e.g., electron source 301 of FIG. 3) may be activated to generate a charged-particle beam (e.g., primary electron beam 302 of FIG. 3). The electron source may be activated by a controller (e.g., controller 50 of FIG. 1). For example, the electron source may be controlled to emit primary electrons to form an electron beam along a primary optical axis (e.g., primary optical axis 300_1 of FIG. 3). The electron source may be activated remotely, for example, by using a software, an application, or a set of instructions for a processor of a controller to power the electron source through a control circuitry.

In step 1320, a beam deflector (e.g., beam deflector 421 of FIG. 4) may be configured to deflect the primary electron beam (e.g., electron beam 403 of FIG. 4) comprising a plurality of electrons (e.g., on-axis electron 403c or chief ray and off-axis electrons 403p1 and 403p2 or margin rays of FIG. 4) away from the primary optical axis at a deflection angle. The deflected primary electron beam may comprise a deflected chief ray 403c-1 incident on a surface (e.g., surface 407 of FIG. 4) of a sample (e.g., sample 408 of FIG. 4) at a desirable tilt angle of incidence with respect to a surface normal of the sample, and away from the primary optical axis. An objective lens (e.g., objective lens 411 of FIG. 4) may be configured to focus the deflected primary electron beams on to the surface of the sample.

In some embodiments, the beam deflector may be configured to deflect on-axis chief ray away from primary optical axis based on an electrical excitation signal comprising a static component and a dynamic component. The electrical excitation signal may comprise, for example, an AC voltage signal. As an example, an amplitude of the electrical excitation signal may be 100±20 V, where 100 V may comprise the static component and ±20V may comprise the dynamic component. The static component of the electrical excitation signal, when applied, may cause the beam deflector to deflect the on-axis chief ray at a desired first beam-tilt angle. An adjustment of the dynamic component may cause the beam deflector to adjust landing position of the on-axis chief ray incident on surface, and thereby scan the region of interest to form the FOV.

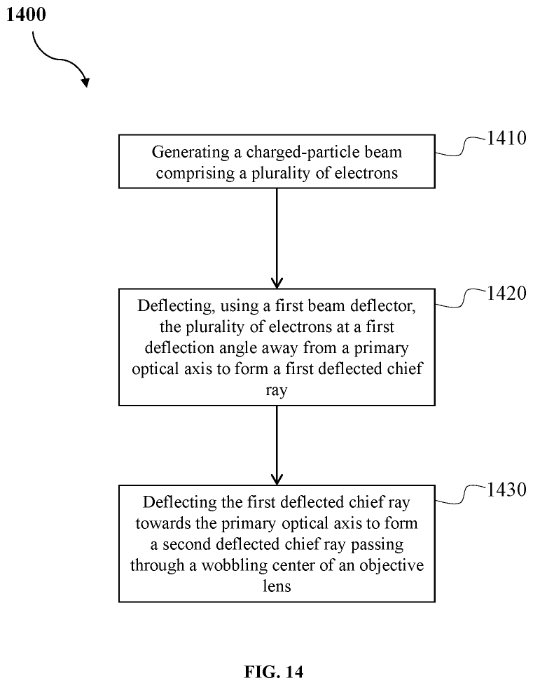

Reference is now made to FIG. 14, which illustrates a process flowchart representing an exemplary method 1400 for imaging a sample using a tilted electron beam in an electron beam tool with a beam-tilt function, consistent with embodiments of the present disclosure. Method 1400 may be performed by controller 50 of EBI system 100, as shown in FIG. 1, for example. Controller 50 may be programmed to implement one or more steps of method 1400. For example, controller 50 may instruct a module of a charged particle beam apparatus to activate a charged-particle source to generate charged particle beam (e.g., electron beam) and carry out other functions.

In step 1410, a charged-particle source (e.g., electron source 601 of FIG. 6) may be activated to generate a charged-particle beam (e.g., primary electron beam 602 of FIG. 6). The electron source may be activated by a controller (e.g., controller 50 of FIG. 1). For example, the electron source may be controlled to emit primary electrons to form an electron beam along a primary optical axis (e.g., primary optical axis 600_1 of FIG. 6). The electron source may be activated remotely, for example, by using a software, an application, or a set of instructions for a processor of a controller to power the electron source through a control circuitry.

In step 1420, a first beam deflector (e.g., beam deflector 621 of FIG. 6) may be configured to deflect the electron beam (e.g., electron beam 602 of FIG. 6) comprising a plurality of electrons (e.g., on-axis electron or chief ray 603c and off-axis electrons or margin rays 603p1 and 603p2 of FIG. 6) away from the primary optical axis at a first deflection angle θ1 and form first deflected chief ray (e.g., first deflected chief ray 603c-1 of FIG. 6). The first beam deflector may deflect the electron beam at the first deflection angle based on a static component of an electrical excitation signal.

In step 1430, a second beam deflector (e.g., beam deflector 622 of FIG. 6), located immediately downstream of the first beam deflector, may deflect the first deflected electron beam back towards the primary optical axis at a second deflection angle θ2 to form second deflected chief ray (e.g., second deflected chief ray 603c-2 of FIG. 6) based on a static component of an electrical excitation signal applied to the second beam deflector. The second deflected chief ray may pass through a wobbling center of an objective lens and land on the sample at a first position away from the primary optical axis with a first beam-tilt angle.

In some embodiments, for beam scanning over the FOV, the first beam deflector may further deflect the electron beam away from the primary optical axis at a third deflection angle θ3 to form a third deflected chief ray based on a dynamic component of an electrical excitation signal applied to the first beam deflector. The second beam deflector may further deflect the electron beam with the third deflected chief ray towards the primary optical axis at a fourth deflection angle θ4 to form a fourth deflected chief ray (e.g., deflected chief ray 603c-4 of FIG. 6) based on a dynamic component of an electrical excitation signal applied to the second beam deflector 622. Adjustment of the dynamic component of the electrical excitation signal may cause the fourth deflected chief ray to pass through a wobbling center of an objective lens and land on the sample at a second position with a second beam-tilt angle. The second position may be different from the first position.

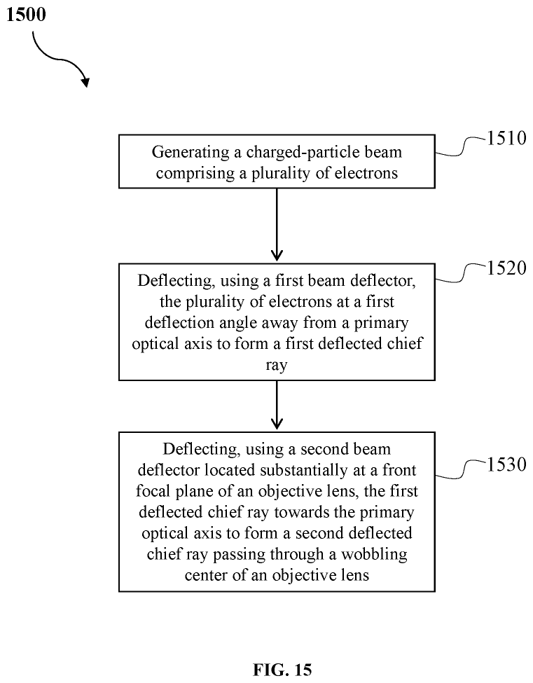

Reference is now made to FIG. 15, which illustrates a process flowchart representing an exemplary method 1500 for imaging a sample using a tilted electron beam in an electron beam metrology tool with a beam-tilt function, consistent with embodiments of the present disclosure. Method 1500 may be performed by controller 50 of EBI system 100, as shown in FIG. 1, for example. Controller 50 may be programmed to implement one or more steps of method 1500. For example, controller 50 may instruct a module of a charged particle beam apparatus to activate a charged-particle source to generate charged particle beam (e.g., electron beam) and carry out other functions.

In step 1510, a charged-particle source (e.g., electron source 701 of FIG. 7) may be activated to generate a charged-particle beam (e.g., primary electron beam 702 of FIG. 7). The electron source may be activated by a controller (e.g., controller 50 of FIG. 1). For example, the electron source may be controlled to emit primary electrons to form an electron beam along a primary optical axis (e.g., primary optical axis 700_1 of FIG. 7). The electron source may be activated remotely, for example, by using a software, an application, or a set of instructions for a processor of a controller to power the electron source through a control circuitry.

In step 1520, a first beam deflector (e.g., beam deflector 721 of FIG. 7) may be configured to deflect an electron beam (e.g., electron beam 703 of FIG. 7) comprising a plurality of electrons (e.g., on-axis electron or chief ray 703c and off-axis electrons or margin rays 703p1 and 703p2 of FIG. 7) away from the primary optical axis at a first deflection angle θ1 and form first deflected chief ray (e.g., first deflected chief ray 703c-1 of FIG. 7). The first beam deflector may deflect the electron beam at the first deflection angle based on a static component of an electrical excitation signal.

In step 1530, a second beam deflector (e.g., beam deflector 722 of FIG. 7), located substantially on a front focal plane (e.g., front focal plane 711-f of FIG. 7) of an objective lens, may deflect the first deflected electron beam back towards the primary optical axis at a second deflection angle θ2 to form second deflected chief ray (e.g., second deflected chief ray 703c-2 of FIG. 7) based on a static component of an electrical excitation signal applied to the second beam deflector. The second deflected chief ray may pass through a wobbling center of the objective lens, and the objective lens may focus the electron beam e on the surface of the sample at a first position (e.g., probe spot 703s of FIG. 7) away from the primary optical axis. The incident second deflected chief ray may form a first beam tilt angle with respect to a surface normal.

In some embodiments, for scanning the beam to form the FOV, the second beam deflector may further deflect the first deflected electron beam back towards the primary optical axis at a third deflection angle θ3 to form third deflected chief ray (e.g., third deflected chief ray 703c-3 of FIG. 7) based on a dynamic component of the electrical excitation signal applied to the second beam deflector. The objective lens may further focus the third deflected electron beam on the surface of the sample at a second position and form a second beam tilt angle of incidence with respect to a surface normal. The incident chief ray may form a second beam tilt angle with respect to a surface normal. The second beam deflector may be at a front focal plane of the objective lens, and therefore the second beam-tilt angle may be substantially equal to the first beam-tilt angle.

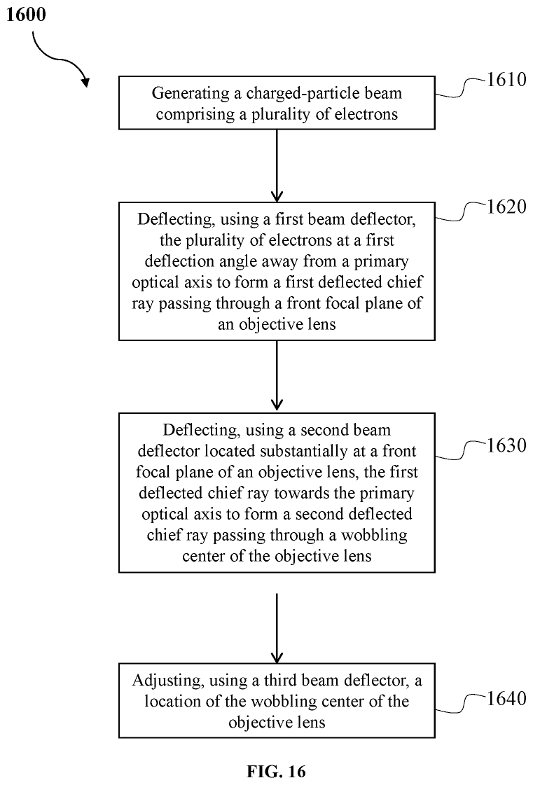

Reference is now made to FIG. 16, which illustrates a process flowchart representing an exemplary method 1600 for imaging a sample using a tilted electron beam in an electron beam metrology tool with a beam-tilt function, consistent with embodiments of the present disclosure. Method 1600 may be performed by controller 50 of EBI system 100, as shown in FIG. 1, for example. Controller 50 may be programmed to implement one or more steps of method 1600. For example, controller 50 may instruct a module of a charged particle beam apparatus to activate a charged-particle source to generate charged particle beam (e.g., electron beam) and carry out other functions.

In step 1610, a charged-particle source (e.g., electron source 801 of FIG. 8) may be activated to generate a charged-particle beam (e.g., primary electron beam 802 of FIG. 8). The electron source may be activated by a controller (e.g., controller 50 of FIG. 1). For example, the electron source may be controlled to emit primary electrons to form an electron beam along a primary optical axis (e.g., primary optical axis 800_1 of FIG. 8). The electron source may be activated remotely, for example, by using a software, an application, or a set of instructions for a processor of a controller to power the electron source through a control circuitry.

In step 1620, a first beam deflector (e.g., beam deflector 821 of FIG. 8) may be configured to deflect an electron beam (e.g., electron beam 803 of FIG. 8) comprising a plurality of electrons (e.g., on-axis chief ray 803c and off-axis electrons or margin rays 803p1 and 803p2 of FIG. 8) away from the primary optical axis at a first deflection angle θ1. The first beam deflector may deflect the electron beam at the first deflection angle, forming the first deflected chief ray based on a static component of an electrical excitation signal to the first beam deflector. The first deflected chief ray may intersect a front focal plane (e.g., front focal plane 811-f of FIG. 8) of an objective lens (e.g., objective lens 811 of FIG. 8) at a first off-axis location (e.g., off-axis location 811-t of FIG. 8).

In step 1630, a second beam deflector (e.g., beam deflector 822 of FIG. 8), located substantially on the front focal plane of the objective lens, may deflect the first deflected chief ray back towards the primary optical axis at a second deflection angle θ2 to form a second deflected chief ray (e.g., second deflected chief ray 803c-2 of FIG. 8) based on a static component of an electrical excitation signal applied to the second beam deflector. The second deflected chief ray may pass through an adjusted wobbling center (e.g., adjusted wobbling center 811-w of FIG. 8) of the objective lens, and land on the surface of the sample at a position of the FOV center in “vertical incidence mode” (e.g., probe spot 803s of FIG. 8) which is substantially coinciding with the primary optical axis. The incident second deflected chief ray may form a desirable first beam tilt angle with respect to a surface normal.

In step 1640, a third deflector (e.g., beam deflector 823 of FIG. 8), located substantially at the objective lens may be configured to adjust the position of the wobbling center of the objective lens to the position of the adjusted wobbling center based on a static component of an electrical excitation signal applied to the third beam deflector. The second deflector may further deflect the primary electron beam to form a FOV on the sample surface, based on a dynamic component of the electrical excitation signal applied to the second deflector. In some embodiments, a dynamic component of the electrical excitation signal applied to the third deflector may further adjust the position of the adjusted wobbling center of the objective lens to another location (e.g., wobbling center 1111-w1 of FIG. 11) so that the second deflected chief ray passes through the adjusted wobbling center over the FOV.

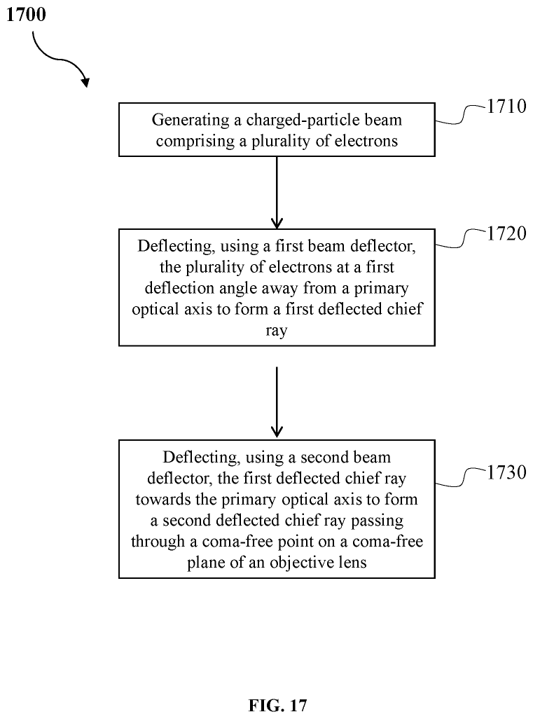

Reference is now made to FIG. 17, which illustrates a process flowchart representing an exemplary method 1700 for imaging a sample using a tilted electron beam in an electron beam metrology tool with a beam-tilt function, consistent with embodiments of the present disclosure. Method 1700 may be performed by controller 50 of EBI system 100, as shown in FIG. 1, for example. Controller 50 may be programmed to implement one or more steps of method 1700. For example, controller 50 may instruct a module of a charged particle beam apparatus to activate a charged-particle source to generate charged particle beam (e.g., electron beam) and carry out other functions.

In step 1710, a charged-particle source (e.g., electron source 1201 of FIG. 12) may be activated to generate a charged-particle beam (e.g., primary electron beam 1202 of FIG. 12). The electron source may be activated by a controller (e.g., controller 50 of FIG. 1). For example, the electron source may be controlled to emit primary electrons to form an electron beam along a primary optical axis (e.g., primary optical axis 1200_1 of FIG. 12). The electron source may be activated remotely, for example, by using a software, an application, or a set of instructions for a processor of a controller to power the electron source through a control circuitry.

In step 1720, a first beam deflector (e.g., beam deflector 1221 of FIG. 12) may be configured to deflect an electron beam (e.g., electron beam 1203 of FIG. 12) comprising a plurality of electrons (e.g., on-axis chief ray 1203c and off-axis margin rays 1203p1 and 1203p2 of FIG. 12) away from the primary optical axis at a first deflection angle θ1. The first beam deflector may deflect the electron beam at the first deflection angle, forming the first deflected chief ray based on a static component of an electrical excitation signal to the first beam deflector.

In step 1730, a second beam deflector (e.g., beam deflector 1222 of FIG. 12) may deflect the first deflected chief ray back towards the primary optical axis such that the chief ray passes through a coma-free point (e.g., coma-free point 1211-cf of FIG. 12) on a coma-free plane (e.g., coma-free plane 1211c of FIG. 12) of the objective lens.

Fabricating complex electrical device structures and stacks, such as in a 3D NAND device with a high production yield, may be limited by the precise patterning of features, e.g., inter-level connections, among other factors. In semiconductor devices, high-aspect ratio (HAR) contact holes may be etched through multiple layers of materials such that an electrical contact may be established between the individual devices and the external environment. As previously described, one of several techniques to inspect complex 3D structures such as HAR contact holes with an overall tilt and internal bending, may be to tilt the electron beam used for imaging. While tilting the beam may be beneficial in some applications, it may offer significant challenges related to efficiency and throughput. For example, one or more beam deflectors employed to tilt the incident beam and the tilted beam trajectory through the objective lens may introduce aberrations of the charged-particle beam, and resultantly negatively impact the image resolution and throughput.

Further, in some cases, the primary electron beam may be tilted by an average tilt-angle to inspect an array of features to enhance inspection throughput. However, doing so may be counter-productive and may negatively impact the throughput of defect detection and wafer inspection, at least because the local tilt-angle for individual features may be different from the average tilt-angle. For example, small shifts in etching condition (based on tilt angle of the contact hole) may result in a large overall misalignment between the bottom of the contact hole and the contact pad, thereby negatively impacting the device performance and/or reliability. Therefore, it may be desirable to determine the tilt-angle for individual contact holes and feed-back or feed-forward the information to allow process optimization to improve wafer yield and throughput.

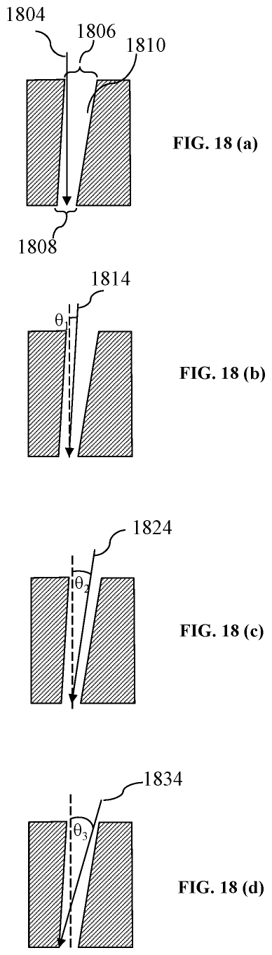

Reference is now made to FIGS. 18a-18d, which illustrate an exemplary range of beam-tilt angles for imaging contact holes in a device, consistent with embodiments of the present disclosure. In some embodiments, the primary charged-particle beam may be tilted at a range of angles with respect to the primary optical axis (e.g., primary optical axis 201 of FIG. 2) to accurately measure the bottom critical dimension of HAR contact holes. In the context of this disclosure and in the field of semiconductor device metrology, critical dimension is a factor which identifies or defines the minimum physical dimension for a semiconductor structure to ensure reliability and performance, which is used to determine the quality of the fabrication process. Bottom critical dimension refers to the critical dimension of the bottom surface of a HAR contact hole and top critical dimension refers to the critical dimension of the top surface of a HAR contact hole.

FIG. 18a illustrates a HAR contact hole 1810 having a top critical dimension 1806 and a bottom critical dimension 1808, and a vertically incident primary charged-particle beam 1804 (e.g., electron beam) imaging HAR contact hole 1810. Based on the tilt-angle of HAR contact hole 1810, some portion of bottom surface of HAR contact hole 1810 may be blocked while imaging using a vertically incident primary charged-particle beam 1804, resulting in an inaccurate measurement of bottom critical dimension 1808. Although FIG. 18a illustrates a tapered cross-section of HAR contact hole 1810 where top critical dimension 1806 is larger than bottom critical dimension 1808, other cross-sections may be possible as well. In some embodiments, based on the etching conditions, HAR contact hole 1810 may have internal bending in addition to an overall tilt such that the slope of HAR contact hole 1810 is discontinuous.

In some embodiments, one or more images of HAR contact hole 1810 may be acquired using vertically incident primary charged-particle beam 1804 and the top critical dimension, the bottom critical dimension, and the overlay measurement between the top and the bottom critical dimensions may be measured based on the acquired images. The angle of incidence of primary charged-particle beam 1804 may be varied within a range of angles to determine the beam-tilt coefficient in the X- and the Y-axes. In some embodiments, the range of angles with respect to the primary optical axis may be −15° to +15°, −10° to +10°, −5° to +5°, −2° to +2°, or −1° to +1°, or any suitable range. The beam-tilt angle of the primary charged-particle beam may be adjusted to be substantially parallel to the tilt angle of HAR contact hole 1810 so that an accurate measurement of bottom critical dimension may be made.

FIG. 18b illustrates a primary charged-particle beam 1814 tilted at an angle θ1 with respect to the primary optical axis (shown as a vertical dashed line). In some embodiments, primary charged-particle beam 1824 may be tilted at an angle θ2 with respect to the primary optical axis, or primary charged-particle beam 1834 may be tilted at an angle θ3 with respect to the primary optical axis, as shown in FIGS. 18c and 18d, respectively.

As an example, apparatus 400 shown in FIG. 4 may be used to adjust the beam-tilt angle of primary charged-particle beam 1804 to image HAR contact hole 1810. As previously described with respect to apparatus 400, a beam deflector (e.g., beam deflector 421) may be configured to deflect primary charged-particle beam 1804 away from the primary optical axis based on an electrical excitation signal comprising a static component and a dynamic component. The electrical excitation signal may comprise, for example, an AC voltage signal. As an example, an amplitude of the electrical excitation signal may be 100±20 V, where 100 V comprises the amplitude of the static component and 20 V comprises the amplitude of the dynamic component. The direction and degree of the beam-tilt angle may be adjusted by adjusting the polarity and amplitude of the static component, and the size and orientation of scanning field of view (FOV) may be adjusted by adjusting the polarity and amplitude of the dynamic component. The static component of the electrical excitation signal, when applied, may cause the beam deflector to deflect on-axis chief ray (e.g., on-axis chief ray 403c) at a desired beam-tilt angle. The dynamic component of the electrical excitation signal, when applied, may cause the beam deflector to scan the on-axis chief ray on a surface (e.g., surface 407) to obtain a desired field-of-view. It is to be appreciated that any of the apparatuses 400, 500, 600, 700, 800, 900, 1000, 1100, or 1200 having a beam-tilt function may be used to adjust the beam-tilt angle of primary charged-particle beam 1804 to inspect HAR contact holes such as HAR contact hole 1810.

In some embodiments, a controller (e.g., controller 50 of FIG. 1) may be configured to adjust the electrical excitation signal applied to the first deflector to cause an adjustment of the beam-tilt angle or the incidence angle. For example, controller 50 may adjust the polarity and amplitude of the static component of the electrical excitation signal applied to the first deflector to adjust the degree and direction of deflection of primary charged-particle beam 1804. The adjustment of the polarity and amplitude of the static component of the electrical excitation signal may be based on a predetermined dimension of HAR contact hole 1810 such as measurement of bottom critical dimension 1808, or top critical dimension 1806, or an overlay between the top and the bottom critical dimensions in X- and Y-axes.

In some embodiments, controller 50 may be further configured to determine a characteristic of a feature such as, for example, HAR contact hole 1810, based on the adjusted beam-tilt angle of primary charged-particle beam 1804. The characteristic of HAR contact hole 1810 may include, but is not limited to, a tilt-angle, or a tilt-direction. In some embodiments, controller 50 may be further configured to associate the adjusted beam-tilt angle with a corresponding HAR contact hole 1810 being imaged. In some embodiments, controller 50 may include timing circuitry to time-stamp the imaging of a HAR contact hole such that the beam-tilt angle utilized to image the HAR contact hole may be mapped to the corresponding HAR contact hole based on time-stamp information. Controller may further be configured to generate a feature-level wafer mapping of adjusted beam-tilt angles utilized to image the corresponding features. A feature, as referred to herein, may include but is not limited to, a contact hole, a via, a HAR contact hole, or a contact pad, among other structures fabricated on a semiconductor wafer.

In some embodiments, controller 50 may be configured to store, for example, the mapping information, the time-stamp information, the feature-level wafer mapping information, and information associated with the adjusted beam-tilt angles, in an internal storage such as a memory of controller 50 or an external storage such as a server or a database in communication with controller 50. The information stored may be accessible to other systems or processes in the semiconductor device fabrication and metrology operations.

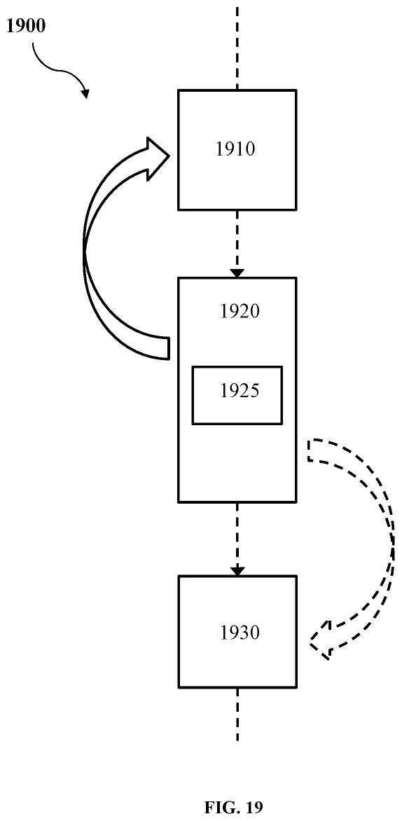

Reference is now made to FIG. 19, which illustrates exemplary feed-back and feed-forward data flow path 1900 to and from a charged-particle beam apparatus, consistent with embodiments of the present disclosure. Exemplary path 1900 may include an etching step performed by an etcher 1910, an in-line metrology step performed by a charged-particle beam apparatus 1920, and a contact-metal deposition step performed by a deposition chamber 1930. It is to be appreciated that path 1900 is exemplary, and process steps may be modified, added to, or removed from path 1900, as appropriate.

As an example, etching step performed by etcher 1910 may comprise an upstream process with respect to the in-line metrology step. In the context of this disclosure, an “upstream” process refers to a process or an operation performed prior to or before the reference process. Contact-metal deposition step performed by deposition chamber 1930 may comprise a downstream process with respect to the in-line metrology step. In the context of this disclosure, a “downstream” process refers to a process or an operation performed subsequently or after the reference process. In some embodiments, charged-particle beam apparatus 1920, also referred to as apparatus

1920, may include controller 1925 and a storage (not shown). Controller 1925 may be substantially similar to and may perform substantially similar functions as controller 50 of FIG. 1. In some embodiments, apparatus 1920 may comprise an in-line metrology apparatus, which is configured to develop feed-back metrology data. For example, controller 1925 of apparatus 1920 may determine the tilt-angle of HAR contact hole 1810 based on the beam-tilt angle used to image HAR contact hole 1810 and may feed-back the determined tilt-angle to an upstream process (e.g., such as the etching process) such that the etching conditions may be optimized or modified for the subsequent wafers being processed through the line. In some embodiments, apparatus 1920 may be configured to develop feed-forward metrology data. For example, controller 1925 may feed-forward the determined tilt-angle to a downstream process such as the metal-contact deposition process such that the deposition conditions may be optimized to form an electrical contact by filling HAR contact hole 1810 by a substantially defect-free contact layer.

In some embodiments, the tilt-angles of a plurality of HAR contact holes may be determined to generate a feature-level wafer mapping of tilt-angles. In some other embodiments, the individual tilt-angles of HAR contact holes may be used to determine an average tilt-angle, or local tilt uniformity for a portion of the wafer such as a die, or a portion of a die, or an array of devices, among other things. The individual tilt-angles or the feature-level wafer mapping of tilt-angles of HAR contact holes may be utilized for upstream and downstream process optimizations.

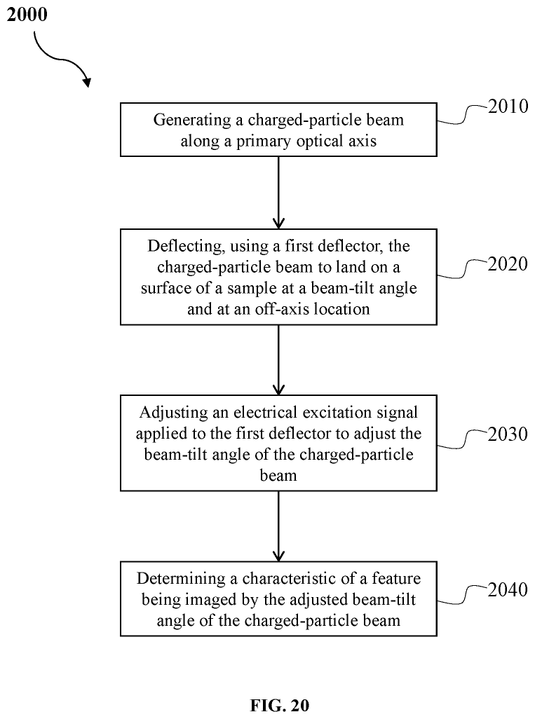

Reference is now made to FIG. 20, which illustrates a process flowchart representing an exemplary method 2000 for imaging a sample using a tilted electron beam in an electron beam metrology tool with a beam-tilt function, consistent with embodiments of the present disclosure. Method 2000 may be performed by controller 50 of EBI system 100, as shown in FIG. 1, for example. Controller 50 may be programmed to implement one or more steps of method 2000. For example, controller 50 may instruct a module of a charged particle beam apparatus to activate a charged-particle source to generate charged particle beam (e.g., electron beam) and carry out other functions.

In step 2010, a charged-particle source (e.g., electron source 301 of FIG. 3) may be activated to generate a charged-particle beam (e.g., primary electron beam 302 of FIG. 3). The electron source may be activated by a controller (e.g., controller 50 of FIG. 1). For example, the electron source may be controlled to emit primary electrons to form an electron beam along a primary optical axis (e.g., primary optical axis 300_1 of FIG. 3). The electron source may be activated remotely, for example, by using a software, an application, or a set of instructions for a processor of a controller to power the electron source through a control circuitry.

In step 2020, a beam deflector (e.g., beam deflector 421 of FIG. 4) may be configured to deflect the primary electron beam (e.g., electron beam 403 of FIG. 4) comprising a plurality of electrons (e.g., on-axis electron 403c or chief ray and off-axis electrons 403p1 and 403p2 or margin rays of FIG. 4) away from the primary optical axis at a deflection angle. The deflected primary electron beam may comprise a deflected chief ray 403c-1 incident on a surface (e.g., surface 407 of FIG. 4) of a sample (e.g., sample 408 of FIG. 4) at a desirable tilt angle of incidence with respect to a surface normal of the sample, and away from the primary optical axis. An objective lens (e.g., objective lens 411 of FIG. 4) may be configured to focus the deflected primary electron beams on to the surface of the sample.

In some embodiments, the beam deflector may be configured to deflect on-axis chief ray away from primary optical axis based on an electrical excitation signal comprising a static component and a dynamic component. The electrical excitation signal may comprise, for example, an AC voltage signal. As an example, an amplitude of the electrical excitation signal may be 100±20 V, where 100 V may comprise the static component and ±20V may comprise the dynamic component. The static component of the electrical excitation signal, when applied, may cause the beam deflector to deflect the on-axis chief ray at a desired first beam-tilt angle. An adjustment of the dynamic component may cause the beam deflector to adjust landing position of the on-axis chief ray incident on surface, and thereby scan the region of interest to form the FOV.

In step 2030, the electrical excitation signal applied to the first deflector may be adjusted to adjust the degree and direction of deflection of the primary electron beam, thereby adjusting the beam-tilt angle of the primary electron beam. In some embodiments, the controller may be configured to adjust the electrical excitation signal applied to the first deflector to cause an adjustment of the beam-tilt angle or the incidence angle. The controller may adjust the polarity and amplitude of the static component of the electrical excitation signal applied to the first deflector to adjust the degree and direction of deflection of primary electron beam. The adjustment of the polarity and amplitude of the static component of the electrical excitation signal may be based on a predetermined dimension of a HAR contact hole (e.g., HAR contact hole 1810 of FIG. 18) such as measurement of bottom critical dimension (e.g., bottom critical dimension 1808 of FIG. 18), or top critical dimension (e.g., top critical dimension 1806 of FIG. 18), or an overlay between the top and the bottom critical dimensions in X-and Y-axes.

In step 2040, a characteristic of the HAR contact hole may be determined based on the adjusted beam-tilt angle of the primary electron beam. The characteristic of HAR contact hole may include, but is not limited to, a tilt-angle, or a tilt-direction. In some embodiments, the controller may associate the adjusted beam-tilt angle with a corresponding HAR contact hole being imaged. In some embodiments, the controller may include timing circuitry to time-stamp the imaging of a HAR contact hole such that the beam-tilt angle utilized to image the HAR contact hole may be mapped to the corresponding HAR contact hole based on time-stamp information. Controller may further generate a feature-level wafer mapping of adjusted beam-tilt angles utilized to image the corresponding features. A feature, as referred to herein, may include but is not limited to, a contact hole, a via, a HAR contact hole, or a contact pad, among other structures fabricated on a semiconductor wafer. Controller may further store, for example, the mapping information, the time-stamp information, the feature-level wafer mapping information, and information associated with the adjusted beam-tilt angles, in an internal storage such as a memory of the controller or an external storage such as a server or a database in communication with the controller. The information stored may be accessible to other systems or processes in the semiconductor device fabrication and metrology operations.

A non-transitory computer readable medium may be provided that stores instructions for a processor of a controller (e.g., controller 50 of FIG. 1) to carry out image inspection, image acquisition, activating charged-particle source, adjusting electrical excitation of stigmators, adjusting landing energy of electrons, adjusting objective lens excitation, stage motion control, activating a beam deflector to deflect primary electron beam, applying electrical excitation signals including AC voltage, adjusting the electrical excitation signal applied to beam deflectors, associating, storing, and providing information related to the determined characteristic of a feature, etc. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A charged-particle beam apparatus, comprising:
a charged-particle source configured to generate a charged-particle beam along a primary optical axis; and
a first deflector configured to deflect the charged-particle beam to land on a surface of a sample at a beam-tilt angle, wherein the first deflector is located substantially at a principal plane of an objective lens.
2. The apparatus of clause 1, wherein the objective lens is configured to focus the charged-particle beam on the surface of the sample at an off-axis location, the charged-particle beam having the beam-tilt angle.
3. The apparatus of any one of clauses 1 and 2, wherein the first deflector is configured to deflect the charged-particle beam based on a first electrical excitation signal comprising a static component and a dynamic component.
4. The apparatus of clause 3, wherein:
the static component is configured to cause the charged-particle beam having the beam-tilt angle land on the surface at the off-axis location; and
the dynamic component is configured to cause the beam to scan a field-of-view (FOV) on the surface, wherein a center of the FOV substantially coincides with the off-axis location.
5. The apparatus of clause 4, wherein an adjustment of the dynamic component causes an adjustment of a size of the FOV, and an adjustment of the static component is configured to enable an adjustment of the off-axis location and the beam-tilt angle.
6. The apparatus of clause 2, further comprising a second deflector located substantially at a front focal plane of the objective lens.
7. The apparatus of clause 6, wherein the second deflector is located between a condenser lens and the first deflector along the primary optical axis.
8. The apparatus of any one of clauses 6 and 7, wherein the second deflector is configured to deflect the charged-particle beam to scan a field-of-view (FOV) based on a dynamic component of a second electrical excitation signal, and wherein a center of the FOV substantially coincides with the off-axis location.
9. The apparatus of clause 8, wherein an adjustment of the dynamic component is configured to cause an adjustment of a size of the FOV, and an adjustment of an electrical excitation signal of the first deflector is configured to enable an adjustment of the center of the FOV.
10. A charged-particle beam apparatus, comprising:
a charged-particle source configured to generate a charged-particle beam along a primary optical axis;
a first deflector configured to deflect the charged-particle beam away from the primary optical axis; and
a second deflector configured to deflect the charged-particle beam back towards the primary optical axis so as to pass through a wobbling center of an objective lens and land on a surface of a sample at a beam-tilt angle, wherein the second deflector is positioned between the first deflector and the sample.
11. The apparatus of clause 10, wherein the objective lens is configured to focus the charged-particle beam on the surface at an off-axis location, the charged-particle beam having the beam-tilt angle.
12. The apparatus of any one of clauses 10 and 11, wherein the first deflector is located between a condenser lens and the second deflector.
13. The apparatus of any one of clauses 10-12, wherein:
the first deflector is configured to deflect the charged-particle beam based on a first static component and a first dynamic component of a first electrical excitation signal;
the second deflector is configured to deflect the charged-particle beam based on a second static component and a second dynamic component of a second electrical excitation signal;
the first and the second static components are configured to deflect the charged-particle beam to form the off-axis location and the beam-tilt angle; and
the first and the second dynamic components are configured to deflect the charged-particle beam to pass through the wobbling center and scan a field-of-view (FOV) on the surface of the sample.
14. The apparatus of clause 13, wherein adjustments of the first and the second dynamic components cause an adjustment of a size of the FOV, and wherein adjustments of the first and the second static components are configured to cause an adjustment of the off-axis location and the beam-tilt angle.
15. The apparatus of any one of clauses 10-12, wherein the second deflector is positioned substantially at a front focal plane of the objective lens.
16. The apparatus of clause 15, wherein
the first deflector is configured to deflect the charged-particle beam based on a first static component of a first electrical excitation signal;
the second deflector is configured to deflect the charged-particle beam based on a second static component and a second dynamic component of a second electrical excitation signal;
the first and the second static components are configured to deflect the charged-particle beam to form the off-axis location and the beam-tilt angle; and
the second dynamic component is configured to deflect the charged-particle beam to scan a field-of-view (FOV) on the surface of the sample.
17. The apparatus of clause 16, wherein an adjustment of the second dynamic component causes an adjustment of a size and an orientation of the FOV, and adjustments of the first and the second static components causes an adjustment of the location and the beam-tilt angle.
18. A charged-particle beam apparatus, comprising:
a charged-particle source configured to generate a charged-particle beam along a primary optical axis;
a first deflector located between the charged-particle source and an objective lens and configured to deflect the charged-particle beam away from the primary optical axis;
a second deflector located substantially at a focal plane of the objective lens and configured to deflect the charged-particle beam back towards the primary optical axis; and
a third deflector located substantially at a principal plane of the objective lens, wherein the third deflector is configured to shift a wobbling center of the objective lens to an off-axis wobbling location, and wherein the first and the second deflectors are configured to deflect the charged-particle beam to pass through the off-axis wobbling location to land on a surface of a sample at a first landing location and having a beam-tilt angle.
19. The apparatus of clause 18, wherein the first deflector is located between a condenser lens and the second deflector along the primary optical axis.
20. The apparatus of any one of clauses 18 and 19, wherein:
the first deflector is configured to deflect the charged-particle beam based on a first static component of a first electrical excitation signal;
the second deflector is configured to deflect the charged-particle beam based on a second static component of a second electrical excitation signal; and
the third deflector is configured to shift the wobbling center based on a third static component of a third electrical excitation signal.
21. The apparatus of clause 20, wherein the second deflector is further configured to deflect the charged-particle beam to scan a field-of-view (FOV) based on a second dynamic component of the second electrical excitation signal.
22. The apparatus of any one of clauses 20 and 21, wherein the second deflector comprises an electrostatic deflector and a magnetic deflector.
23. The apparatus of clause 22, wherein the second static component is configured to be applied to the magnetic deflector and the second dynamic component is configured to be applied to the electrostatic deflector.
24. The apparatus of any one of clauses 21-23, wherein an adjustment of the second dynamic component is configured to enable an adjustment of a size and an orientation of the FOV, and adjustments of the first, second and third static components are configured to enable an adjustment of the beam-tilt angle and the first landing location.
25. The apparatus of any one of clauses 18-24, wherein the first landing location substantially coincides with the primary optical axis.
26. The apparatus of any one of clauses 18-25, wherein the objective lens is configured to focus the beam onto the surface of the sample.
27. The apparatus of clause 18, further comprising a fourth deflector and a fifth deflector, both located between the first deflector and the second deflector along the primary optical axis.
28. The apparatus of clause 27, wherein the fourth deflector is configured to deflect the beam based on a fourth dynamic component of a fourth electrical excitation signal applied to the fourth deflector and the fifth deflector is configured to deflect the beam based on a fifth dynamic component of a fifth electrical excitation signal applied to the fifth deflector.
29. The apparatus of any one of clauses 27 and 28, wherein the fourth and the fifth deflectors deflect the charged-particle beam to scan a field-of-view (FOV) on the surface of the sample.
30. The apparatus of clause 22, wherein the second deflector is located at a focal plane of the objective lens.
31. The apparatus of any one of clauses 18-30, further comprising a beam-limit aperture array movable along a plane substantially normal to the primary optical axis and configured to limit a beam current of the charged-particle beam.
32. A charged-particle beam apparatus, comprising:
a charged-particle source configured to generate a charged-particle beam along a primary optical axis;
a first deflector located between the charged-particle source and an objective lens and configured to deflect the charged-particle beam away from the primary optical axis;
a second deflector located substantially at a focal plane of the objective lens and configured to deflect the charged-particle beam back towards the primary optical axis; and
a third deflector located substantially at a principal plane of the objective lens, wherein the third deflector is configured to shift a wobbling center of the objective lens to an off-axis wobbling location such that the charged-particle beam passes through the wobbling center of the objective lens.
33. The apparatus of clause 32, wherein the first and the second deflectors are further configured to deflect the charged-particle beam to scan a field-of-view on a surface of a sample.
34. The apparatus of any one of clauses 32 and 33, wherein the first deflector is located between a condenser lens and the second deflector, and wherein the second deflector is located between the first deflector and the third deflector along the primary optical axis.
35. The apparatus of any one of clauses 32-34, wherein:
the first deflector is configured to deflect the charged-particle beam to pass through a first off-axis wobbling location based on a first static component of a first electrical excitation signal;
the second deflector is configured to deflect the charged-particle beam to pass through the first off-axis wobbling location based on a second static component of a second electrical excitation signal; and
the third deflector is configured to shift the wobbling center to the first off-axis wobbling location based on a third static component of a third electrical excitation signal.
36. The apparatus of clause 35, wherein:
the first deflector is configured to deflect the charged-particle beam to scan the FOV based on a first dynamic component of the first electrical excitation signal;
the second deflector is configured to deflect the charged-particle beam to scan the FOV based on a second dynamic component of the second electrical excitation signal; and
the third deflector is configured to shift the wobbling center of the objective lens to a second off-axis wobbling location based on a third dynamic component of a third electrical excitation signal such that the charged-particle beam, while scanning, passes through the second off-axis wobbling location.
37. The apparatus of any one of clauses 35 and 36, wherein an adjustment of the first and the second dynamic components are configured to enable an adjustment of a size of the FOV, and an adjustment of the first and the second static components are configured to enable an adjustment of a beam-tilt angle of incidence of the charged-particle beam and a center of the FOV on the surface of the sample.
38. The apparatus of any one of clauses 32-37, wherein each of the first, the second, and the third deflector comprises an electrostatic deflector and a magnetic deflector.
39. The apparatus of clause 38, wherein a static component of an electrical excitation signal is configured to be applied to the corresponding magnetic deflector and a dynamic component of the electrical excitation signal is configured to be applied to the corresponding electrostatic deflector.
40. The apparatus of clause 32, further comprising a fourth deflector and a fifth deflector, both located between the first deflector and the second deflector along the primary optical axis.
41. The apparatus of clause 40, wherein the fourth deflector is configured to deflect the charged-particle beam based on a fourth dynamic component of a fourth electrical excitation signal applied to the fourth deflector and the fifth deflector is configured to deflect the charged-particle beam based on a fifth dynamic component of a fifth electrical excitation signal applied to the fifth deflector.
42. The apparatus of any one of clauses 40 and 41, wherein the fourth and the fifth deflectors deflect the charged-particle beam to scan a field-of-view (FOV) on the surface of the sample.
43. The apparatus of any one of clauses 32-42, further comprising a beam-limit aperture array movable along a plane substantially normal to the primary optical axis and configured to limit a beam current of the charged-particle beam.
44. A charged-particle beam apparatus, comprising:
a charged-particle source configured to generate a charged-particle beam along a primary optical axis;
a first deflector located between the charged-particle source and an objective lens and configured to deflect the charged-particle beam away from the primary optical axis;
a second deflector located between the first deflector and the objective lens and configured to deflect the charged-particle beam to pass through a coma-free point on a coma-free plane of the objective lens; and
a dispersion compensator located between the charged-particle source and the first deflector along the primary optical axis.
45. The apparatus of clause 44, wherein the first deflector is located between a condenser lens and the second deflector along the primary optical axis, and the second deflector is located between the first deflector and the coma-free plane of the objective lens.
46. The apparatus of any one of clauses 44 and 45, wherein a first static component of a first electrical excitation signal applied to the first deflector and a second static component of a second electrical excitation signal applied to the second deflector are configured to deflect the charged-particle beam to pass through the coma-free point and land on a surface of a sample at a landing location with a beam-tilt angle.
47. The apparatus of clause 46, wherein the first and the second deflectors are configured to deflect the charged-particle beam to scan a field-of-view (FOV) on the surface of the sample based on a first dynamic component and a second dynamic component of the first and the second electrical excitation signals, respectively.
48. The apparatus of clause 47, wherein an adjustment of the first and the second dynamic components is configured to enable an adjustment of a size of the FOV, and an adjustment of the first and the second static components is configured to enable an adjustment of the beam-tilt angle and the landing location of the charged-particle beam on the surface of the sample.
49. The apparatus of any one of clauses 44-48, wherein the dispersion compensator comprises an electrostatic deflector and a magnetic deflector.
50. The apparatus of any one of clauses 44-49, wherein the dispersion compensator is further configured to compensate a chromatic aberration of the objective lens.
51. The apparatus of any one of clauses 44-50, wherein one or both of the first and the second deflectors are further configured to compensate an astigmatism of the objective lens.
52. The apparatus of any one of clauses 44-51, wherein an adjustment of an electrical excitation of the objective lens enables compensation of a field-curvature aberration of the objective lens.
53. The apparatus of any one of clauses 44-52, further comprising a beam-limit aperture array movable along a plane substantially normal to the primary optical axis and configured to limit a beam current of the charged-particle beam.
54. A method for imaging a sample using a tilted charged-particle beam, the method comprising:
generating a charged-particle beam along a primary optical axis; and
deflecting, using a first deflector, the charged-particle beam to land on a surface of a sample at a beam-tilt angle and at an off-axis location, wherein the first deflector is located substantially at a principal plane of an objective lens.
55. The method of clause 54, further comprising focusing, using the objective lens, the charged-particle beam on the surface of the sample at the off-axis location.
56. The method of any one of clauses 54 and 55, further comprising deflecting, using the first deflector, the charged-particle beam based on a first electrical excitation signal comprising a static component.
57. The method of clause 56, wherein the first electrical excitation signal further comprises a dynamic component.
58. The method of clause 57, further comprising:
applying the static component of the first electrical excitation signal to the first deflector to deflect the charged-particle beam to land on the surface at the off-axis location; and
applying the dynamic component of the first electrical excitation signal to the first deflector to deflect the charged-particle beam to scan a field-of-view (FOV) on the surface, wherein a center of the FOV substantially coincides with the off-axis location.
59. The method of clause 58, further comprising adjusting the dynamic component to adjust a size of the FOV, and adjusting the static component to adjust the off-axis location and the beam-tilt angle.
60. The method of clause 56, further comprising:
applying the static component of the first electrical excitation signal to the first deflector to deflect the charged-particle beam to land on the surface at the off-axis location;
applying a dynamic component of a second electrical excitation signal to a second deflector to deflect the charged-particle beam to scan a field-of-view (FOV) on the surface, wherein a center of the FOV substantially coincides with the off-axis location; and
adjusting a dynamic component of a second electrical excitation signal applied to a second deflector to adjust a size and an orientation of the FOV, and adjusting the static component of the first electrical excitation signal to adjust a center of the FOV, wherein the second deflector is located substantially at a front focal plane of the objective lens.
61. A method for imaging a sample using a tilted charged-particle beam, the method comprising:
generating a charged-particle beam along a primary optical axis;
deflecting, using a first deflector, the charged-particle beam away from the primary optical axis; and
deflecting, using a second deflector, the charged-particle beam back towards the primary optical axis so as to pass through a wobbling center of an objective lens and land on a surface of a sample at a beam-tilt angle.
62. The method of clause 61, further comprising focusing, using the objective lens, the charged-particle beam on the surface of the sample at an off-axis location.
63. The method of clause 62, further comprising:
deflecting the charged-particle beam based on a first static component and a first dynamic component of a first electrical excitation signal;
deflecting the charged-particle beam based on a second static component and a second dynamic component of a second electrical excitation signal;
deflecting, based on the first and the second static components, the charged-particle beam to form the off-axis location and the beam-tilt angle; and
deflecting, based on the first and the second dynamic components, the charged-particle beam to pass through the wobbling center and scan a field of view (FOV) on the surface of the sample.
64. The method of clause 63, further comprising adjusting the first and the second dynamic components to adjust a size of the FOV, and adjusting the first and the second static components to adjust the off-axis location and the beam-tilt angle.
65. The method of clause 61, wherein the second deflector is located substantially at a front focal plane of the objective lens.
66. The method of clause 65, further comprising:
deflecting the charged-particle beam based on a first static component of a first electrical excitation signal;
deflecting the charged-particle beam based on a second static component and a second dynamic component of a second electrical excitation signal;
deflecting, based on the first and the second static components, the charged-particle beam to form an off-axis location on the surface of the sample and the beam-tilt angle; and
deflecting, based on the second dynamic component, the charged-particle beam to scan a field-of-view on the surface of the sample.
67. The method of clause 66, further comprising adjusting the second dynamic component to adjust a size and an orientation of the FOV, and adjusting the first and the second static components to adjust the off-axis location and the beam-tilt angle.
68. A method for imaging a sample using a tilted charged-particle beam, the method comprising:
generating a charged-particle beam along a primary optical axis;
deflecting, using a first deflector, the charged-particle beam away from the primary optical axis, the first deflector located between a charged-particle source and an objective lens;
deflecting, using a second deflector, the charged-particle beam back towards the primary optical axis; and
shifting, using a third deflector, a wobbling center of the objective lens to an off-axis wobbling location, wherein the first and the second deflectors are configured to deflect the charged-particle beam to pass through the off-axis wobbling location to land on a surface of a sample at a first landing location and having a beam-tilt angle.
69. The method of clause 68, further comprising:
applying a first static component of a first electrical excitation signal to the first deflector to deflect the charged-particle beam;
applying a second static component of a second electrical excitation signal to the second deflector to deflect the charged-particle beam; and
applying a third static component of a third electrical excitation signal to the third deflector to shift the wobbling center of the objective lens.
70. The method of clause 69, further comprising applying a second dynamic component of the second electrical excitation signal to the second deflector to deflect the charged-particle beam to scan a field-of-view (FOV).
71. The method of any one of clauses 68-70, wherein the second deflector comprises an electrostatic deflector and a magnetic deflector, and wherein the second deflector is located substantially at a front focal plane of the objective lens.
72. The method of clause 71, further comprising applying the second static component to the magnetic deflector and the second dynamic component to the electrostatic deflector.
73. The method of any one of clauses 70-72, further comprising adjusting the second dynamic component to adjust a size and an orientation of the FOV, and adjusting the first, the second, and the third static components to adjust the beam-tilt angle and the first landing location.
74. The method of clause 68, further comprising:
deflecting, using a fourth deflector, the charged-particle beam based on a fourth dynamic component of a fourth electrical excitation signal applied to the fourth deflector; and
deflecting, using a fifth deflector, the charged-particle beam based on a fifth dynamic component of a fifth electrical excitation signal applied to the fifth deflector.
75. The method of clause 74, wherein the fourth and the fifth deflectors are located between the first deflector and the second deflector along the primary optical axis, and wherein the fourth and the fifth deflectors are configured to deflect the charged-particle beam to scan a field-of-view (FOV) on the surface of the sample.
76. A method for imaging a sample using a tilted charged-particle beam, the method comprising:
generating a charged-particle beam along a primary optical axis;
deflecting, using a first deflector, the charged-particle beam away from the primary optical axis, the first deflector located between a charged-particle source and an objective lens;
deflecting, using a second deflector, the charged-particle beam back towards the primary optical axis, the second deflector located substantially at a focal plane of the objective lens; and
shifting, using a third deflector, a wobbling center of the objective lens, wherein
the first and the second deflectors are further configured to deflect the charged-particle beam to scan a field-of-view (FOV) on a surface of a sample, and wherein the third deflector is configured to shift the wobbling center of the objective lens to an off-axis wobbling location such that the charged-particle beam passes through the wobbling center of the objective lens.
77. The method of clause 76, further comprising:
deflecting the charged-particle beam to pass through a first off-axis wobbling location based on a first static component of a first electrical excitation signal;
deflecting the charged-particle beam to pass through the first off-axis wobbling location based on a second static component of a second electrical excitation signal; and
shifting the wobbling center to the first off-axis wobbling location based on a third static component of a third electrical excitation signal.
78. The method of clause 77, further comprising:
deflecting the charged-particle beam to scan the FOV based on a first dynamic component of the first electrical excitation signal;
deflecting the charged-particle beam to scan the FOV based on a second dynamic component of the second electrical excitation signal; and
shifting the wobbling center to a second off-axis wobbling location based on a third dynamic component of the third electrical excitation signal such that the charged-particle beam, while scanning, passes through the second off-axis wobbling location.
79. The method of clause 78, further comprising adjusting the first, the second and the third dynamic components to adjust a size of the FOV, and adjusting the first, the second and the third static components to adjust a beam-tilt angle of the charged-particle beam and a center of the FOV on the surface of the sample.
80. The method of any one of clauses 76-79, wherein each of the first, the second, and the third deflector comprises an electrostatic deflector and a magnetic deflector.
81. The method of clause 80, further comprising applying a static component of an electrical excitation signal to a corresponding magnetic deflector and a dynamic component of the electrical excitation signal to a corresponding electrostatic deflector.
82. A method for imaging a sample using a tilted charged-particle beam, the method comprising:
generating a charged-particle beam along a primary optical axis;
deflecting, using a first deflector, the charged-particle beam away from the primary optical axis; and
deflecting, using a second deflector, the charged-particle beam to pass through a coma-free point on a coma-free plane of an objective lens, wherein the second beam deflector is located between the first deflector and the objective lens.
83. The method of clause 82, further comprising applying a first static component of a first electrical excitation signal to the first deflector and applying a second static component of a second electrical excitation signal applied to the second deflector, the first and the second static components configured to deflect the charged-particle beam to pass through the coma-free point and land on a surface of a sample at a landing location with a beam-tilt angle.
84. The method of clause 83, further comprising applying a first dynamic component of the first electrical excitation signal and applying a second dynamic component of the second electrical excitation signal to scan a field-of-view (FOV) on the surface of the sample.
85. The method of clause 84, wherein adjusting the first and the second dynamic components adjusts a size of the FOV, and wherein adjusting the first and the second static components adjusts the beam-tilt angle of the charged-particle beam and a center of the FOV on the surface of the sample.
86. The method of any one of clauses 82-85, further comprising adjusting an electrical excitation of the objective lens to adjust a field-curvature aberration of the objective lens.
87. The method of any one of clauses 82-86, further comprising compensating, using a dispersion compensator, a chromatic aberration of the objective lens, wherein the dispersion compensator comprises an electrostatic deflector and a magnetic deflector.
88. The method of any one of clauses 82-87, further comprising compensating, using one or both of the first and the second deflectors, an astigmatism of the objective lens.
89. A non-transitory computer readable medium storing a set of instructions that is executable by one or more processors of a charged-particle beam apparatus to cause the charged-particle beam apparatus to perform a method of imaging a sample using a tilted charged-particle beam, the method comprising:
activating a charged-particle source to generate a primary charged-particle beam;
deflecting, at a first deflector, the charged-particle beam to land on a surface of a sample at a beam-tilt angle, wherein the first deflector is located substantially at a principal plane of an objective lens.
90. A non-transitory computer readable medium storing a set of instructions that is executable by one or more processors of a charged-particle beam apparatus to cause the charged-particle beam apparatus to perform a method of imaging a sample using a tilted charged-particle beam, the method comprising:
activating a charged-particle source to generate a primary charged-particle beam;
deflecting the charged-particle beam away from a primary optical axis; and
deflecting the charged-particle beam back towards the primary optical axis so as to pass through a wobbling center of an objective lens and land on a surface of a sample at a beam-tilt angle.
91. A non-transitory computer readable medium storing a set of instructions that is executable by one or more processors of a charged-particle beam apparatus comprising a first deflector, a second deflector, a third deflector, and an objective lens, to cause the charged-particle beam apparatus to perform a method of imaging a sample using a tilted charged-particle beam, the method comprising:
activating a charged-particle source to generate a primary charged-particle beam;
deflecting, using a first deflector, the charged-particle beam away from the primary optical axis;
deflecting, using a second deflector, the charged-particle beam back towards the primary optical axis; and
shifting, using a third deflector, a wobbling center of the objective lens, wherein
the first and the second deflectors are further configured to deflect the charged-particle beam to scan a field-of-view (FOV) on a surface of a sample, and wherein the third deflector is configured to shift the wobbling center of the objective lens to an off-axis wobbling location such that the charged-particle beam passes through the wobbling center of the objective lens.
92. A non-transitory computer readable medium storing a set of instructions that is executable by one or more processors of a charged-particle beam apparatus to cause the charged-particle beam apparatus to perform a method of imaging a sample using a tilted charged-particle beam, the method comprising:
activating a charged-particle source to generate a primary charged-particle beam;
deflecting the charged-particle beam away from the primary optical axis; and
deflecting the charged-particle beam to pass through a coma-free point on a coma-free plane of an objective lens.
93. A charged-particle beam apparatus comprising:
a charged-particle source configured to generate a charged-particle beam along a primary optical axis;
a first deflector located substantially at a principal plane of an objective lens and configured to deflect the charged-particle beam to land on a surface of a sample at a beam-tilt angle; and
a controller having circuitry configured to:
   adjust an electrical excitation signal applied to the first deflector to cause an adjustment of the beam-tilt angle of the charged-particle beam; and
   determine a characteristic of a feature being imaged by the adjusted beam-tilt angle of the charged-particle beam,
   wherein the adjustment of the electrical excitation signal is based on a predetermined dimension of the feature being imaged.
94. The apparatus of clause 93, wherein the controller includes circuitry further configured to associate the adjusted beam-tilt angle with a corresponding feature being imaged.
95. The apparatus of any one of clauses 93 and 94, wherein the controller includes circuitry further configured to feed back the determined characteristic of the feature to an upstream process.
96. The apparatus of any one of clauses 93-95, wherein the controller includes circuitry further configured to feed forward the determined characteristic of the feature to a downstream process.
97. The apparatus of any one of clauses 93-96, wherein the feature comprises a high aspect ratio contact hole, and wherein the characteristic of the feature comprises a tilt angle of the high aspect ratio contact hole.
98. The apparatus of any one of clauses 93-97, wherein the predetermined dimension of the feature comprises a top critical dimension, a bottom critical dimension, or an overlay between the top and the bottom critical dimensions.
99. The apparatus of clause 98, wherein the overlay is based on an overlap of images of a top surface and a bottom surface of the feature, and wherein the top and the bottom surface images are acquired using a no-tilt charged-particle beam.
100. The apparatus of any one of clauses 93-99, wherein the objective lens is configured to focus the charged-particle beam on the surface of the sample at an off-axis location, the charged-particle beam having the beam-tilt angle.
101. The apparatus of clause 100, wherein the electrical excitation signal comprises:
a static component configured to cause the charged-particle beam having the beam-tilt angle land on the surface at the off-axis location; and
a dynamic component configured to cause the beam to scan a field-of-view (FOV) on the surface, wherein a center of the FOV substantially coincides with the off-axis location.
102. The apparatus of clause 101, wherein an adjustment of the dynamic component causes an adjustment of a size of the FOV, and an adjustment of the static component is configured to enable an adjustment of the off-axis location and the beam-tilt angle.
103. The apparatus of any one of clauses 93-102, further comprising a second deflector located substantially at a front focal plane of the objective lens.
104. The apparatus of clause 103, wherein the second deflector is located between a condenser lens and the first deflector along the primary optical axis.
105. A method of imaging a sample using a tilted charged-particle beam, the method comprising:
generating a charged-particle beam along a primary optical axis;
deflecting, using a first deflector, the charged-particle beam to land on a surface of a sample at a beam-tilt angle and at an off-axis location, wherein the first deflector is located substantially at a principal plane of an objective lens;
adjusting an electrical excitation signal applied to the first deflector to adjust the beam-tilt angle of the charged-particle beam; and
determining a characteristic of a feature being imaged by the adjusted beam-tilt angle of the charged-particle beam,
wherein the first electrical excitation signal is adjusted based on a predetermined dimension of the feature being imaged.
106. The method of clause 105, further comprising associating the adjusted beam-tilt angle with a corresponding feature being imaged.
107. The method of any one of clauses 105 and 106, further comprising feeding back the determined characteristic of the feature to an upstream process.
108. The method of any one of clauses 105-107, further comprising feeding forward the determined characteristic of the feature to a downstream process.
109. The method of any one of clauses 105-108, wherein the feature comprises a high aspect ratio contact hole, and wherein the characteristic of the feature comprises a tilt angle of the high aspect ratio contact hole.
110. The method of any one of clauses 105-109, wherein the predetermined dimension of the feature comprises a top critical dimension, a bottom critical dimension, or an overlay between the top and the bottom critical dimensions.
111. The method of any one of clauses 105-110, further comprising:
applying a static component of the electrical excitation signal to the first deflector to deflect the charged-particle beam to land on the surface at the off-axis location; and
applying a dynamic component of the electrical excitation signal to the first deflector to deflect the charged-particle beam to scan a field-of-view (FOV) on the surface, wherein a center of the FOV substantially coincides with the off-axis location.
112. A non-transitory computer readable medium storing a set of instructions that is executable by one or more processors of a charged-particle beam apparatus to cause the charged-particle beam apparatus to perform a method, the method comprising:
generating a charged-particle beam along a primary optical axis;
deflecting, using a first deflector, the charged-particle beam to land on a surface of a sample at a beam-tilt angle and at an off-axis location, wherein the first deflector is located substantially at a principal plane of an objective lens;
adjusting an electrical excitation signal applied to the first deflector to adjust the beam-tilt angle of the charged-particle beam; and
determining a characteristic of a feature being imaged by the adjusted beam-tilt angle of the charged-particle beam,
wherein the first electrical excitation signal is adjusted based on a predetermined dimension of the feature being imaged.
113. The non-transitory computer readable medium of clause 112, wherein the set of instructions that is executable by one or more processors of the charged-particle beam apparatus to cause the charged-particle beam apparatus to further perform associating the adjusted beam-tilt angle with a corresponding feature being imaged.
114. The non-transitory computer readable medium of clause 112, wherein the set of instructions that is executable by one or more processors of the charged-particle beam apparatus to cause the charged-particle beam apparatus to further perform:
feeding back the determined characteristic of the feature to an upstream process; and
feeding forward the determined characteristic of the feature to a downstream process.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A charged-particle beam apparatus, comprising:
a charged-particle source configured to generate a charged-particle beam along a primary optical axis; and
a first deflector configured to deflect the charged-particle beam to land on a surface of a sample at a beam-tilt angle, wherein the first deflector is located substantially at a principal plane of an objective lens.

2. The apparatus of claim 1, wherein the objective lens is configured to focus the charged-particle beam on the surface of the sample at an off-axis location, the charged-particle beam having the beam-tilt angle.

3. The apparatus of claim 1, wherein the first deflector is configured to deflect the charged-particle beam based on a first electrical excitation signal comprising a static component and a dynamic component.

4. The apparatus of claim 3, wherein:
the static component is configured to cause the charged-particle beam having the beam-tilt angle land on the surface at an off-axis location; and
the dynamic component is configured to cause the beam to scan a field-of-view (FOV) on the surface, wherein a center of the FOV substantially coincides with the off-axis location.

5. The apparatus of claim 4, wherein an adjustment of the dynamic component causes an adjustment of a size of the FOV, and an adjustment of the static component is configured to enable an adjustment of the off-axis location and the beam-tilt angle.

6. The apparatus of claim 2, further comprising a second deflector located substantially at a front focal plane of the objective lens.

7. The apparatus of claim 6, wherein the second deflector is located between a condenser lens and the first deflector along the primary optical axis.

8. The apparatus of claim 6, wherein the second deflector is configured to deflect the charged-particle beam to scan a field-of-view (FOV) based on a dynamic component of a second electrical excitation signal, and wherein a center of the FOV substantially coincides with the off-axis location.

9. The apparatus of claim 8, wherein an adjustment of the dynamic component of the second electrical excitation signal is configured to cause an adjustment of a size of the FOV, and an adjustment of a first electrical excitation signal of the first deflector is configured to enable an adjustment of the center of the FOV.

10. A method for imaging a sample using a tilted charged-particle beam, the method comprising:
generating a charged-particle beam along a primary optical axis; and
deflecting, using a first deflector, the charged-particle beam to land on a surface of a sample at a beam-tilt angle and at an off-axis location, wherein the first deflector is located substantially at a principal plane of an objective lens.

11. The method of claim 10, further comprising deflecting, using the first deflector, the charged-particle beam based on a first electrical excitation signal comprising a static component and a dynamic component.

12. The method of claim 11, further comprising:
applying the static component of the first electrical excitation signal to the first deflector to deflect the charged-particle beam to land on the surface at the off-axis location; and
applying the dynamic component of the first electrical excitation signal to the first deflector to deflect the charged-particle beam to scan a field-of-view (FOV) on the surface, wherein a center of the FOV substantially coincides with the off-axis location.

13. The method of claim 12, further comprising adjusting the dynamic component to adjust a size of the FOV, and adjusting the static component to adjust the off-axis location and the beam-tilt angle.

14. The method of claim 10, further comprising:
applying a dynamic component of a second electrical excitation signal to a second deflector to deflect the charged-particle beam to scan a field-of-view (FOV) on the surface, wherein a center of the FOV substantially coincides with the off-axis location; and
adjusting a dynamic component of the second electrical excitation signal applied to the second deflector to adjust a size and an orientation of the FOV, and adjusting a static component of a first electrical excitation signal to adjust a center of the FOV, wherein the second deflector is located substantially at a front focal plane of the objective lens.

15. A non-transitory computer readable medium storing a set of instructions that is executable by one or more processors of a charged-particle beam apparatus to cause the charged-particle beam apparatus to perform a method of imaging a sample using a tilted charged-particle beam, the method comprising:
activating a charged-particle source to generate a primary charged-particle beam;
deflecting, at a first deflector, the charged-particle beam to land on a surface of a sample at a beam-tilt angle, wherein the first deflector is located substantially at a principal plane of an objective lens.

16. A charged-particle beam apparatus, comprising:
a charged-particle source configured to generate a charged-particle beam along a primary optical axis;
a first deflector configured to deflect the charged-particle beam away from the primary optical axis; and
a second deflector configured to deflect the charged-particle beam back towards the primary optical axis so as to pass through a wobbling center of an objective lens and land on a surface of a sample at a beam-tilt angle, wherein the second deflector is positioned between the first deflector and the sample.

17. The apparatus of claim 16, wherein the objective lens is configured to focus the charged-particle beam on the surface at an off-axis location, the charged-particle beam having the beam-tilt angle.

18. The apparatus of claim 16, wherein the first deflector is located between a condenser lens and the second deflector.

19. The apparatus of claim 16, wherein:
the first deflector is configured to deflect the charged-particle beam based on a first static component and a first dynamic component of a first electrical excitation signal;
the second deflector is configured to deflect the charged-particle beam based on a second static component and a second dynamic component of a second electrical excitation signal;
the first and the second static components are configured to deflect the charged-particle beam to form an off-axis location and the beam-tilt angle; and
the first and the second dynamic components are configured to deflect the charged-particle beam to pass through the wobbling center and scan a field-of-view (FOV) on the surface of the sample.

20. The apparatus of claim 19, wherein adjustments of the first and the second dynamic components cause an adjustment of a size of the FOV, and wherein adjustments of the first and the second static components are configured to cause an adjustment of the off-axis location and the beam-tilt angle.
